(19) United States
(12) Patent Application Publication
(10) Pub. No.: US 2026/0006968 A1
(43) Pub. Date: Jan. 1, 2026

(54) DISPLAY DEVICE, AND ELECTRONIC DEVICE

(71) Applicant: Samsung Display Co., LTD., Yongin-si (KR)

(72) Inventors: Sung Chul HONG, Yongin-si (KR); Do Yeong PARK, Yongin-si (KR)

(73) Assignee: Samsung Display Co., LTD., Yongin-si (KR)

(21) Appl. No.: 19/180,443

(22) Filed: Apr. 16, 2025

(30) Foreign Application Priority Data
Jun. 28, 2024 (KR) 10-2024-0085637

(51) Int. Cl. H10H 29/80; H10H 29/01; H10H 29/37; H10K 102/10

(52) U.S. Cl. CPC H10H 29/8323; H10H 29/032; H10H 29/034; H10H 29/37; H10H 29/8325; H10H 29/842; H10K 2102/102; H10K 2102/103

(57) ABSTRACT

A display device includes a display element layer on a substrate, the display element layer includes an anode electrode and a cathode electrode spaced apart on the substrate, an overcoat pattern on the anode electrode, a light emitting element on the overcoat pattern and including a first end portion adjacent to the overcoat pattern and a second end portion spaced apart from the first end portion, a first transparent electrode layer on the overcoat pattern and electrically connecting the anode electrode to the first end portion of the light emitting element, at least one insulating layer on the first transparent electrode layer and the cathode electrode, and a second transparent electrode layer on the at least one insulating layer and electrically connecting the cathode electrode to the second end portion of the light emitting element.

### CROSS-REFERENCE TO RELATED APPLICATION(S)

This application claims priority to and benefits of Korean Patent Application No. 10-2024-0085637 under 35 U.S.C. § 119, filed on Jun. 28, 2024 in the Korean Intellectual Property Office, the entire contents of which are incorporated herein by reference.

### BACKGROUND

### 1. Technical Field

The disclosure relates to a display device, and an electronic device.

### 2. Description of the Related Art

An importance of a display device has been increased with a development of a multimedia. In response thereof, the use of display devices such as liquid crystal display devices, organic light emitting display devices, and inorganic light emitting display devices is increasing. Research is being actively conducted on micro-LED that may achieve faster response speeds and higher brightness compared to the conventional LED.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments are directed to a display device with improved display quality and a manufacturing method thereof. For example, the display device can improve display quality by increasing contact stability by increasing a contact area between a light emitting element and a transparent electrode layer connected to an anode electrode.

A display device according to an embodiment may include a substrate extending in a first direction and a second direction intersecting the first direction; and a display element layer disposed on the substrate in a third direction intersecting the first direction and the second direction, wherein the display element layer may include an anode electrode and a cathode electrode spaced apart from each other in the second direction on the substrate, an overcoat pattern disposed on the anode electrode, a light emitting element disposed on the overcoat pattern and including a first end portion adjacent to the overcoat pattern and a second end portion spaced apart from the first end portion in the third direction, a first transparent electrode layer disposed on the overcoat pattern and electrically connecting the anode electrode to the first end portion of the light emitting element, at least one insulating layer disposed on the first transparent electrode layer and the cathode electrode, and a second transparent electrode layer disposed on the at least one insulating layer and electrically connecting the cathode electrode to the second end portion of the light emitting element.

The second transparent electrode layer may contact the second end portion of the light emitting element and may be electrically connected to the cathode electrode through a contact hole penetrating the at least one insulating layer.

The contact hole may overlap the cathode electrode.

The contact hole may be spaced apart from the light emitting element in the second direction without overlapping the light emitting element.

The first transparent electrode layer may contact the overcoat pattern and the first end portion of the light emitting element, and the second transparent electrode layer may electrically contact the second end portion of the light emitting element.

The overcoat pattern may be disposed between the anode electrode and the first end portion of the light emitting element.

The first end portion of the light emitting element may contact the overcoat pattern.

The at least one insulating layer may include a first insulating layer disposed on each of the anode electrode and the cathode electrode, and a second insulating layer disposed on the first insulating layer.

The first insulating layer may contact the first transparent electrode layer.

The light emitting element may have a side surface disposed between the first end portion and the second end portion, and the second insulating layer may contact the side surface of the light emitting element.

The first transparent electrode layer and the second transparent electrode layer may be spaced apart from each other in the third direction with the at least one insulating layer disposed between the first transparent electrode layer and the second transparent electrode layer, and may include a same material.

The display device may further include a bank disposed on the anode electrode and the cathode electrode, and include openings exposing a portion of each of the anode electrode and the cathode electrode, wherein a portion of the anode electrode and the first transparent electrode layer may electrically contact each other in one of the openings of the bank.

A display device according to an embodiment may include a substrate extending in a first direction and a second direction intersecting the first direction; and a display element layer disposed on the substrate in a third direction intersecting the first direction and the second direction, wherein the display element layer may include an anode electrode disposed on the substrate, an overcoat pattern disposed on the anode electrode, a light emitting element disposed on the overcoat pattern and including a first end portion adjacent to the overcoat pattern and a second end portion spaced apart from the first end portion in the third direction, a first transparent electrode layer disposed on the overcoat pattern and electrically connecting the anode electrode to the first end portion of the light emitting element, at least one insulating layer disposed on the first transparent electrode layer, and a cathode electrode disposed on the at least one insulating layer and electrically connected to the second end portion of the light emitting element, and wherein the first transparent electrode layer electrically contacts the first end portion of the light emitting element.

The first transparent electrode layer may contact the first end portion of the light emitting element and the overcoat pattern.

The overcoat pattern may be disposed between the anode electrode and the first end portion of the light emitting element.

The first end portion of the light emitting element may contact the overcoat pattern.

An electronic device may include a display device and a substrate, wherein the display device includes the display element layer, and the display element layer is disposed on the substrate.

The electronic device may be at least one of a smart watch, a mobile phone, a smartphone, a portable computer, a tablet personal computer (PC), a watch phone, an automotive display, a smart glass, a portable multimedia player (PMP), a navigation system, an ultra mobile computer (UMPC), a head mounted display (HMD) device, a virtual reality (VR) device, a mixed reality (MR) device, and an augmented reality (AR) device.

### BRIEF DESCRIPTION OF THE DRAWINGS

The above and other aspects and features of the disclosure will become more apparent by describing in detail embodiments thereof with reference to the attached drawings, in which:

FIG. 1 is a block diagram showing an embodiment of a display device.

FIG. 2 is a block diagram showing an embodiment of one of sub-pixels of FIG. 1.

FIG. 3 is a schematic plan view showing an embodiment of a display panel of FIG. 1.

FIG. 4 is a schematic cross-sectional view showing an embodiment of a display panel of FIG. 3.

FIG. 5 is a schematic cross-sectional view showing an embodiment of a display panel of FIG. 3.

FIG. 6 is a schematic plan view showing an embodiment of one of pixels of FIG. 3.

FIG. 7 is a schematic cross-sectional view taken along line I-I′ of FIG. 6.

FIG. 8 is a schematic cross-sectional view taken along line II-II′ of FIG. 6.

FIG. 9 is a schematic plan view showing an embodiment of one of pixels of FIG. 3.

FIG. 10 is a schematic plan view showing an embodiment of one of pixels of FIG. 3.

FIG. 11 is a schematic cross-sectional view taken along line III-III′ of FIG. 10.

FIG. 12 is a schematic cross-sectional view taken along line IV-IV′ of FIG. 10.

FIG. 13 is a flowchart showing a manufacturing method of a display device according to an embodiment.

FIGS. 14 to 23 are drawings showing an example of a manufacturing method of a display device of FIG. 13.

FIG. 24 is a block diagram showing an embodiment of a display system.

FIGS. 25 to 28 are schematic perspective views showing application examples of a display system of FIG. 24.

### DETAILED DESCRIPTION OF THE EMBODIMENTS

Hereinafter, an embodiment according to the disclosure will be described in detail with reference to the attached drawings. It should be noted that the parts necessary to understand the operation according to the disclosure will be described in the following description, and the description of other parts may be omitted to not obscure the gist of the disclosure. The disclosure is not limited to the embodiments described herein and may be embodied in other forms. However, the embodiments described herein are provided to explain in detail to enable those skilled in the art to readily implement the technical idea of the disclosure.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

Throughout the specification, when a part is said to be “connected” to another part, this includes not only the case where it is “directly connected” but also the case where it is “indirectly connected” with another element interposed therebetween. The terms used in this specification are for the purpose of describing the embodiments and is not intended to limit the disclosure. In this disclosure below, when it is described that one “includes” some elements, it should be understood that it may include only those elements, or it may include other elements as well as those elements if there is no specific limitation.

Here, terms such as first, second, etc. may be used to describe various components, but these components are not limited to these terms. These terms are used only to distinguish one constituent element from another constituent element. Accordingly, the first component may be referred to as the second component within the scope of what is disclosed herein.

Spatially relative terms such as “below,” “above,” etc. may be used for descriptive purposes, thereby describing the relationship of one element or feature to another element(s) or feature(s) as shown in the drawings. Spatially relative terms are intended to include different directions in use, operation, and/or manufacture in addition to the directions depicted in the drawings. For example, if the device shown in the drawings is turned over, elements depicted as being disposed “below” other elements or features may be disposed “above” the other elements or features. Accordingly, in an embodiment, the term “below” may include both above and below directions. The device may be oriented in other directions (for example, rotated by 90 degrees or in other orientations), and thus the spatially relative terms used herein should be interpreted accordingly.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

Various embodiments are described with reference to drawings that schematize embodiments. Accordingly, it will be expected that the shapes may vary depending, for example, on tolerances and/or manufacturing techniques. Accordingly, embodiments disclosed herein should not be construed as being limited to the shapes shown, and should be construed to include changes in shapes that occur, for example, as a result of manufacturing. As such, the shapes shown in the drawings may not depict the actual shapes of areas of the device, and the embodiments are not limited thereto.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments may be described and illustrated in the accompanying drawings in terms of functional blocks, units, and/or modules.

Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies.

In the case of the blocks, units, and/or modules being implemented by microprocessors or other similar hardware, they may be programmed and controlled using software (for example, microcode) to perform various functions discussed herein and may optionally be driven by firmware and/or software.

It is also contemplated that each block, unit, and/or module may be implemented by dedicated hardware, or as a combination of dedicated hardware to perform some functions and a processor (for example, one or more programmed microprocessors and associated circuitry) to perform other functions.

Each block, unit, and/or module of embodiments may be physically separated into two or more interacting and discrete blocks, units, and/or modules without departing from the scope of the disclosure.

Further, the blocks, units, and/or modules of embodiments may be physically combined into more complex blocks, units, and/or modules without departing from the scope of the disclosure.

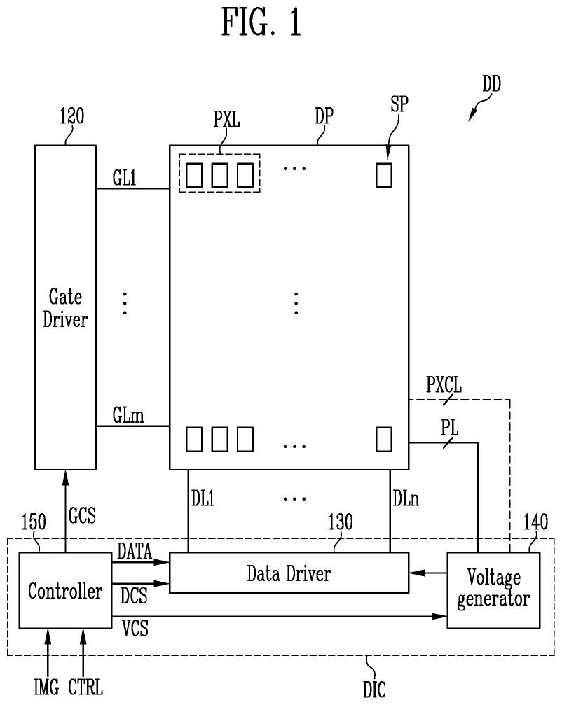

FIG. 1 is a block diagram showing an embodiment of a display device.

Referring to FIG. 1, a display device DD may include a display panel DP, a gate driver 120, a data driver 130, a voltage generator 140, and a controller 150.

The display panel DP may include sub-pixels SP. The sub-pixels SP may be connected to the gate driver 120 through the first to m-th gate lines GL1 to GLm. The sub-pixels SP may be connected to the data driver 130 through the first to n-th data lines DL1 to DLn.

The sub-pixels SP may generate light of two or more colors. For example, each of the sub-pixels SP may generate light such as red, green, blue, cyan, magenta, yellow, etc.

Two or more sub-pixels among the sub-pixels SP may constitute one pixel PXL. For example, the pixel PXL may include three sub-pixels as shown in FIG. 1. In this way, the pixel PXL may emit light of various colors and various brightnesses depending on the combination of light emitted from the sub-pixels included in the pixel.

The gate driver 120 may be connected to sub-pixels SP arranged (or disposed) in the row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating the start of each frame, a horizontal synchronization signal, and the like within the spirit and the scope of the disclosure.

The gate driver 120 may be disposed on one side (or a side) of the display panel DP. However, the embodiments are not limited thereto. For example, the gate driver 120 may be divided into two or more drivers separated physically and/or logically, and such drivers may be disposed on one side of the display panel DP and on the other side of the display panel DP opposite the one side. In this way, the gate driver 120 may be disposed around the display panel DP in various forms according to embodiments.

The data driver 130 may be connected to sub-pixels SP arranged in the column direction through the first to n-th data lines DL1 to DLn. The data driver 130 may receive image data DATA and a data control signal DCS from the controller 150. The data driver 130 may operate in response to the data control signal DCS. In embodiments, the data control signal DCS may include a source start signal, a source shift clock, a source output enable signal, and the like within the spirit and the scope of the disclosure.

The data driver 130 may receive voltages from the voltage generator 140. The data driver 130 may apply data signals having grayscale voltages corresponding to image data DATA to the first to n-th data lines DL1 to DLn using the received voltages. In case that a gate signal is applied to each of the first to m-th gate lines GL1 to GLm, data signals corresponding to the image data DATA may be applied to the data lines DL1 to DLn. Accordingly, the sub-pixels SP may generate light corresponding to data signals, and the display panel DP may display an image.

In embodiments, the gate driver 120 and data driver 130 may include complementary metal-oxide semiconductor (CMOS) circuit elements.

The voltage generator 140 may operate in response to a voltage control signal VCS from controller 150. The voltage generator 140 may be configured to generate voltages and provide the generated voltages to components of a display device DD, such as the gate driver 120, the data driver 130, and the controller 150. The voltage generator 140 may generate voltages by receiving an input voltage from outside the display device DD and regulating the received voltage.

The voltage generator 140 may generate a first power voltage and a second power voltage. The generated first and second power voltages may be provided to the sub-pixels SP through power lines PL. In other embodiments, at least one of the first and second power voltages may be provided from outside the display device DD.

The voltage generator 140 may provide various voltages and/or signals. For example, the voltage generator 140 may provide one or more initialization voltages applied to the sub-pixels SP. For example, during a sensing operation to sense electrical characteristics of the transistors and/or light emitting elements of the sub-pixels SP, a selectable reference voltage may be applied to the first to n-th data lines DL1 to DLn, and the voltage generator 140 may generate the reference voltage and transmit it to the data driver 130. For example, during a display operation to display an image on the display panel DP, common pixel control signals may be applied to the sub-pixels SP, and the voltage generator 140 may generate the pixel control signals. In embodiments, the voltage generator 140 may provide pixel control signals to the sub-pixels SP through the pixel control lines PXCL. In FIG. 1, the pixel control lines PXCL are shown as connected between the voltage generator 140 and the display panel DP, but the embodiments are not limited thereto. For example, the pixel control lines PXCL may be connected between the gate driver 120 and the display panel DP. In this case, pixel control signals may be transmitted from the voltage generator 140 to the pixel control lines PXCL through the gate driver 120.

The controller 150 may control various operations of the display device DD. The controller 150 may receive input image data IMG and a corresponding control signal CTRL from the outside. The controller 150 may provide a gate control signal GCS, a data control signal DCS, and a voltage control signal VCS in response to the control signal CTRL.

The controller 150 may convert the input image data IMG to suit the display device DD or the display panel DP and output image data DATA. In embodiments, the controller 150 may output image data DATA by aligning the input image data IMG to suit the sub-pixels SP in units of row.

Two or more components of the data driver 130, voltage generator 140, and controller 150 may be mounted on one integrated circuit. As shown in FIG. 1, the data driver 130, voltage generator 140, and controller 150 may be included in a driver integrated circuit (DIC). In this case, the data driver 130, voltage generator 140, and controller 150 may be functionally separate components in one driver integrated circuit (DIC). In other embodiments, at least one of the data driver 130, the voltage generator 140, and the controller 150 may be provided as a separate component from the driver integrated circuit (DIC).

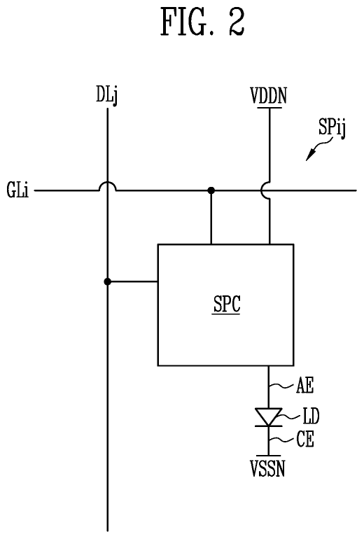

FIG. 2 is a block diagram showing an embodiment of one of the sub-pixels of FIG. 1. In FIG. 2, a sub-pixel SPij arranged in the i-th row (i is an integer greater than or equal to 1 and less than or equal to m) and the j-th column (j is an integer greater than or equal to 1 and less than or equal to n) among the sub-pixels SP of FIG. 1, may be shown as an example.

Referring to FIG. 2, the sub-pixel SPij may include a sub-pixel circuit SPC and a light emitting element LD.

The light emitting element LD may be connected between the first power voltage node VDDN and the second power voltage node VSSN. The first power voltage node VDDN may be connected to one of the power lines PL in FIG. 1 and receive the first power voltage. The second power voltage node VSSN may be connected to another one of the power lines PL of FIG. 1 and may receive the second power voltage. The first power voltage may have a higher voltage level than the second power voltage.

The light emitting element LD may be connected between the anode electrode AE and the cathode electrode CE. The anode electrode AE may be connected to the first power voltage node VDDN through the sub-pixel circuit SPC. For example, the anode electrode AE may be connected to the first power voltage node VDDN through one or more transistors included in the sub-pixel circuit SPC. The cathode electrode CE may be connected to the second power voltage node VSSN. The light emitting element LD may be configured to emit light depending on the current flowing from the anode electrode AE to the cathode electrode CE.

The sub-pixel circuit SPC may be connected to the i-th gate line GLi among the first to m-th gate lines GL1 to GLm of FIG. 1 and the j-th data line DLj among the first to n-th data lines DL1 to DLn of FIG. 1. In response to the gate signal received through the i-th gate line GLi, the sub-pixel circuit SPC may control the light emitting element LD to emit light depending on the data signal received through the j-th data line DLj. In embodiments, the sub-pixel circuit SPC may be further connected to the pixel control lines PXCL of FIG. 1. In this case, the sub-pixel circuit SPC may control the light emitting element LD in further response to pixel control signals received through the pixel control lines PXCL.

For these operations, the sub-pixel circuit SPC may include circuit elements, such as transistors and one or more capacitors.

The transistors of the sub-pixel circuit SPC may include P-type transistors and/or N-type transistors. In embodiments, transistors of the sub-pixel circuit SPC may include a metal oxide silicon field effect transistor (MOSFET). In embodiments, transistors of the sub-pixel circuit SPC may include an amorphous silicon semiconductor, a monocrystalline silicon semiconductor, a polycrystalline silicon semiconductor, an oxide semiconductor, etc.

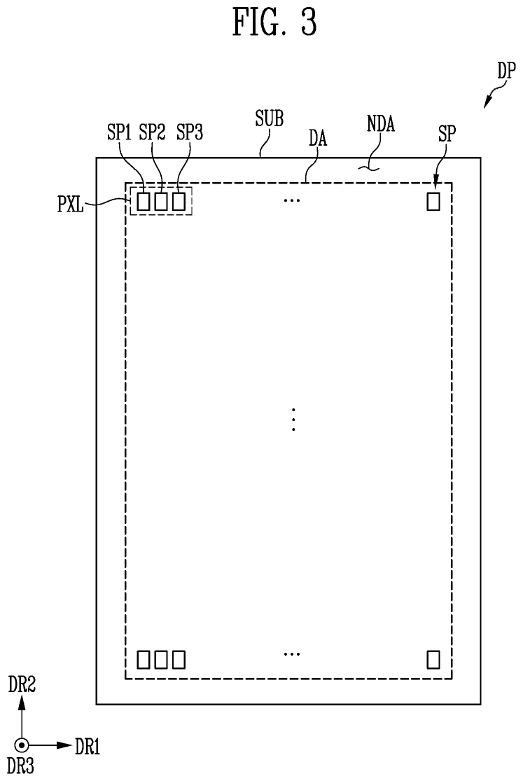

FIG. 3 is a schematic plan view showing an embodiment of a display panel of FIG. 1.

Referring to FIG. 3, the display panel DP may include a display area DA and a non-display area NDA. The display panel DP may display an image through the display area DA. The non-display area NDA may be disposed around the display area DA.

The display panel DP may include sub-pixels SP in the display area DA. The sub-pixels SP may be arranged in the first direction DR1 and the second direction DR2 that intersects the first direction DR1. For example, the sub-pixels SP may be arranged in a matrix form in the first direction DR1 and the second direction DR2. For another example, the sub-pixels SP may be arranged in a zigzag form or pattern in the first direction DR1 and the second direction DR2. The arrangement of the sub-pixels SP may vary according to embodiments. The first direction DR1 may be a row direction, and the second direction DR2 may be a column direction.

Two or more sub-pixels among the sub-pixels SP may constitute one pixel PXL. In FIG. 3, the pixel PXL is shown as including three sub-pixels SP1 to SP3, but the embodiments are not limited thereto. For example, the pixel PXL may include two sub-pixels. Hereinafter, for convenience of description, it is assumed that the pixel PXL may include first to third sub-pixels SP1 to SP3.

Each of the first to third sub-pixels SP1 to SP3 may generate light of one of various colors such as red, green, blue, cyan, magenta, yellow, etc. Hereinafter, for clear and concise description, it is assumed that the first sub-pixel SP1 is configured to generate red-colored light, the second sub-pixel SP2 is configured to generate green-colored light, and the third sub-pixel SP3 is configured to generate blue-colored light.

Each of the first to third sub-pixels SP1 to SP3 may include at least one light emitting element configured to generate light. In embodiments, the light emitting elements of the first to third sub-pixels SP1 to SP3 may generate light of the same color. For example, the light emitting elements of the first to third sub-pixels SP1 to SP3 may generate blue color light. In other embodiments, the light emitting elements of the first to third sub-pixels SP1 to SP3 may generate light of different colors. For example, the light emitting elements of the first to third sub-pixels SP1 to SP3 may generate red color light, green color, and blue color light, respectively.

A display panel capable of self-luminescence, such as a light emitting diode (LED) display panel that uses micro- or nano-scale light emitting diodes as a light emitting element, an organic light emitting (OLED) display panel that uses organic light emitting diodes as a light emitting element, may be used as the display panel DP.

Components for controlling the sub-pixels SP may be disposed in the non-display area NDA. Wires connected to the sub-pixels SP, for example, the first to m-th gate lines GL1 to GLm of FIG. 1, the first to n-th data lines DL1 to DLn, and the power lines PL, and the pixel control lines PXCL may be disposed in the non-display area NDA.

At least one of the gate driver 120, data driver 130, voltage generator 140, and controller 150 of FIG. 1 may be disposed in the non-display area NDA of the display panel DP. In embodiments, the gate driver 120 may be disposed in the non-display area NDA. In this case, the data driver 130, voltage generator 140, and controller 150 may be implemented as a driver integrated circuit DIC of FIG. 1 that is separated from the display panel DP, and the driver integrated circuit DIC may be connected to wires disposed in the non-display area NDA. In other embodiments, the gate driver 120 may be implemented as one integrated circuit separate from the display panel DP along with the data driver 130, voltage generator 140, and controller 150.

In embodiments, the display area DA may have various shapes. The display area DA may have a closed loop shape including straight and/or curved sides. For example, the display area DA may have shapes such as a polygon, circle, semicircle, or ellipse.

In embodiments, the display panel DP may have a flat display surface. In other embodiments, the display panel DP may have a display surface that is at least partially round. In embodiments, the display panel DP may be bendable, foldable, or rollable. In these cases, the display panel DP and/or the substrate of the display panel DP may include materials having flexible properties.

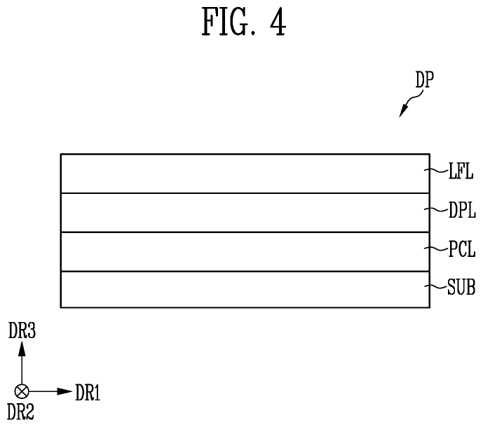

FIG. 4 is a schematic cross-sectional view showing an embodiment of a display panel of FIG. 3.

Referring to FIG. 4, the display panel DP may include a substrate SUB, and a pixel circuit layer PCL, a display element layer DPL, and a light functional layer LFL that are sequentially stacked in the third direction DR3 intersecting the first and second directions DR1 and DR2 on the substrate SUB.

The substrate SUB may be made of an insulating material such as glass or resin. For example, the substrate SUB may include a glass substrate. For another example, the substrate SUB may include a PI (polyimide) substrate. As another example, the substrate SUB may include a silicon wafer substrate formed using a semiconductor process.

In embodiments, the substrate SUB may be made of a flexible material that can be bent or folded, and may have a single-layer structure or a multi-layer structure. For example, the flexible material may include at least one of polystyrene, polyvinyl alcohol, polymethyl methacrylate, polyethersulfone, polyacrylate, polyether imide, polyetherimide, poly ethylene naphthalate, polyethylene terephthalate, polyphenylene sulfide, polyarylate, polyimide, polycarbonate, triacetate cellulose, and cellulose acetate propionate. However, the embodiments are not limited thereto.

The pixel circuit layer PCL may be disposed on the substrate SUB. The pixel circuit layer PCL may include insulating layers and semiconductor patterns and conductive patterns disposed between the insulating layers. The conductive patterns of the pixel circuit layer PCL may function as circuit elements, wires, etc.

The circuit elements of the pixel circuit layer PCL may include sub-pixel circuits SPC (see FIG. 2) of each of the sub-pixels SP of FIG. 3. In other words, the circuit elements of the pixel circuit layer PCL may be composed of transistors of the sub-pixel circuit SPC and one or more capacitors.

The wires of the pixel circuit layer PCL may include wires connected to sub-pixels SP. The wires of the pixel circuit layer PCL may include various signal lines and/or voltage lines desirable to drive the display element layer DPL.

The display element layer DPL may be disposed on the pixel circuit layer PCL. The display element layer DPL may include light emitting elements of sub-pixels SP.

The light function layer LFL may be disposed on a display element layer DPL. The light function layer LFL may include light conversion patterns having color conversion particles and/or scattering particles. For example, the color conversion particles could include quantum dots. The quantum dots may change a wavelength (or color) of light emitted from the display element layer DPL. The light functional layer LFL may further include light scattering patterns having scattering particles. In embodiments, the light conversion patterns and light scattering patterns may be omitted.

The light function layer LFL may further include a color filter layer including color filters. The color filters may selectively transmit light of a given wavelength (or, a given color). In embodiments, the color filter layer may be omitted.

A window may be provided on the light function layer LFL to protect the exposed surface (or upper surface) of the display panel DP. The window may protect the display panel DP from external impact. The window may be combined to the light functional layer LFL using an optically transparent adhesive (or bonding) member. The window may have a multiple layer structure formed of at least one selected from a glass substrate, a plastic film, and a plastic substrate. Such a multi-layer structure may be formed by using a continuous process or a bonding process using an adhesive layer. All or part of a window may be flexible.

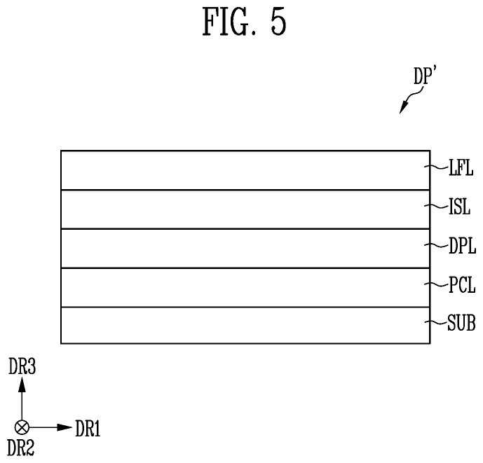

FIG. 5 is a schematic cross-sectional view showing an embodiment of a display panel of FIG. 3.

Referring to FIG. 5, the display panel DP′ may include a substrate SUB, a pixel circuit layer PCL, a display element layer DPL, an input sensing layer ISL, and a light function layer LFL. The substrate SUB, the pixel circuit layer PCL, the display element layer DPL, and the light function layer LFL may be configured similarly to the substrate SUB, the pixel circuit layer PCL, the display element layer DPL, and the light function layer LFL described with reference to FIG. 4. Hereinafter, redundant descriptions may be omitted.

The input sensing layer ISL may sense the user' input on an upper surface (or display surface) of the display panel DP′. The input sensing layer ISL may include configurations suitable for sensing external objects, such as a user's hand, a pen, etc. For example, the input sensing layer ISL may include touch electrodes.

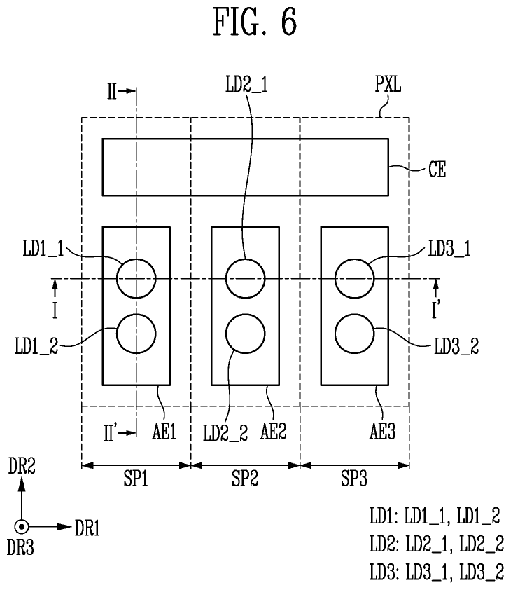

FIG. 6 is a schematic plan view showing an embodiment of one of pixels of FIG. 3.

Referring to FIG. 6, the pixel PXL may include first to third sub-pixels SP1 to SP3. The first to third sub-pixels SP1 to SP3 may be arranged in the first direction DR1. However, the arrangement of pixels PXL is not limited thereto and may vary depending on the embodiments. For example, the first to third sub-pixels SP1 to SP3 may be arranged in a zigzag form or pattern.

First to third anode electrodes AE1 to AE3 may be respectively disposed in the first to third sub-pixels SP1 to SP3. The first anode electrode AE1 may be provided as an anode electrode AE (see FIG. 2) connected to a sub-pixel circuit SPC (see FIG. 2) of the first sub-pixel SP1. The second anode electrode AE2 may be provided as an anode electrode AE connected to the sub-pixel circuit SPC of the second sub-pixel SP2. The third anode electrode AE3 may be provided as an anode electrode AE connected to the sub-pixel circuit SPC of the third sub-pixel SP3.

The cathode electrode CE may be spaced apart from the first to third anode electrodes AE1 to AE3. The cathode electrode CE may be disposed at the same height as the first to third anode electrodes AE1 to AE3. The cathode electrode CE may be spaced apart from the first to third anode electrodes AE1 to AE3 in the second direction DR2. In embodiments, the cathode electrode CE may extend in the first direction DR1 and be used as a common electrode for the first to third sub-pixels SP1 to SP3. Although not shown, the cathode electrode CE may extend in the second direction DR2 as well as the first direction DR1 and may be used as a common electrode for all of the sub-pixels SP of FIG. 3. The cathode electrode CE may be used as a common electrode for the pixel PXL and other pixels adjacent to the pixel PXL. As such, the cathode electrode CE may have various shapes.

One or more first light emitting elements LD1_1 and LD1_2, one or more second light emitting elements LD2_1 and LD2_2 (or, LD2_1″ and LD2_2″), and one or more third light emitting elements LD3_1 and LD3_2 (or, LD3_2″) may be disposed on the first to third anode electrodes AE1 to AE3. The first light emitting elements LD1 may be connected to the first anode electrode AE1. The second light emitting elements LD2 may be connected to the second anode electrode AE2. The third light emitting elements LD3 may be connected to the third anode electrode AE3. In case that light emitting elements are provided in each sub-pixel, each anode electrode may have a shape extending in a given direction, such as the second direction DR2, and the light emitting elements connected thereto may be arranged in the same direction.

The first light emitting elements LD1 may be provided as light emitting elements LD of FIG. 2 included in the first sub-pixel SP1. The second light emitting elements LD2 may be provided as light emitting elements LD of FIG. 2 included in the second sub-pixel SP2. The third light emitting elements LD3 may be provided as light emitting elements LD of FIG. 2 included in the third sub-pixel SP3. In case that light emitting elements are provided in one sub-pixel, the light emitting elements may be connected in parallel between the anode electrode and the cathode electrode to be provided as the light emitting element LD of FIG. 2.

The first light emitting elements LD1, the second light emitting elements LD2, and the third light emitting elements LD3 may be inorganic light emitting diodes including inorganic light emitting materials. However, embodiments are not limited thereto, and for example, organic light emitting diodes may be used.

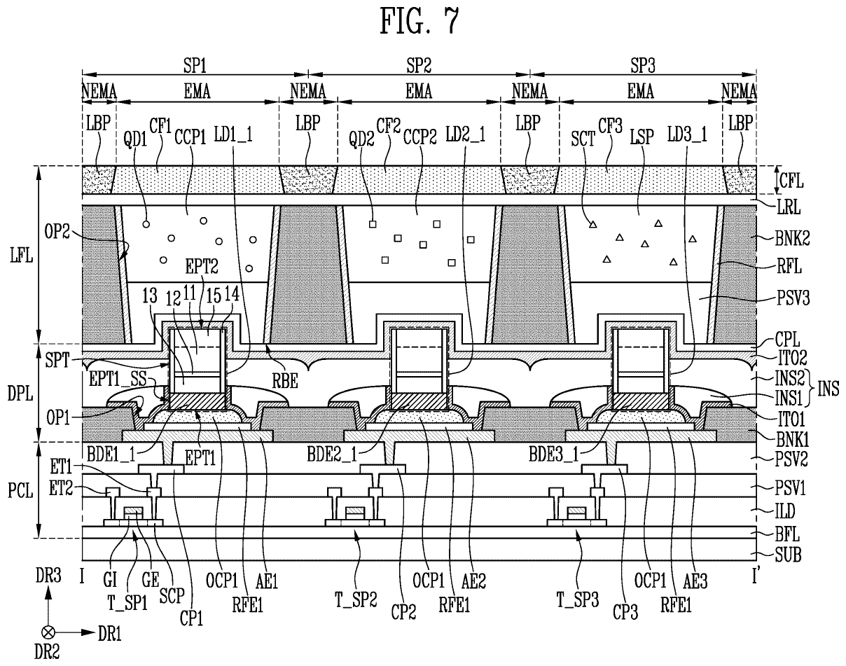

FIG. 7 is a schematic cross-sectional view taken along line I-I′ of FIG. 6.

Referring to FIGS. 6 and 7, the pixel circuit layer PCL, the display element layer DPL, and the light function layer LFL may be sequentially disposed on the substrate SUB.

The substrate SUB may extend in the first direction DR1 and the second direction DR2 intersecting the first direction DR1. The pixel circuit layer PCL, the display element layer DPL, and the light function layer LFL may be disposed on the substrate SUB in the third direction DR3 intersecting the first and second directions DR1 and DR2.

The pixel circuit layer PCL may include insulating layers, semiconductor patterns, and conductive patterns stacked on a substrate SUB. The insulating layers may include a buffer layer BFL, one or more interlayer insulating layers ILD, and one or more passivation layers PSV1 and PSV2. The semiconductor patterns and conductive patterns may be disposed between the insulating layers. The conductive patterns may include at least one material selected from copper (Cu), molybdenum (Mo), tungsten (W), aluminum neodymium (AlNd), titanium (Ti), aluminum (Al), and silver (Ag).

As described with reference to FIG. 2, each of the sub-pixel circuits SPC (see FIG. 2) of the first to third sub-pixels SP1 to SP3 may include transistors and one or more capacitors. Semiconductor patterns and conductive patterns of the pixel circuit layer PCL may function as transistors and capacitors of the sub-pixel circuit SPC. The conductive patterns of the pixel circuit layer PCL may further function as wires, for example, the first to m-th gate lines GL1 to GLm, the first to n-th data lines DL1 to DLn, the power lines PL, and the pixel control lines PXCL of FIG. 1.

The buffer layer BFL may be disposed on one surface or a surface of the substrate SUB. The buffer layer BFL may prevent impurities from diffusing into circuit elements and wires included in the pixel circuit layer PCL. The buffer layer BFL may include an inorganic insulating layer including an inorganic material. In embodiments, the buffer layer BFL may include at least one of a metal oxide such as silicon nitride (SiNₓ), silicon oxide (SiOₓ), silicon oxynitride (SiOₓN_{y}), or aluminum oxide (AlOₓ). The buffer layer BFL may be provided as a single layer or multiple layers. In case that the buffer layer BFL is provided as multiple layers, each layer may be formed of a same material or different materials.

In embodiments, one or more barrier layers may be disposed between the substrate SUB and the buffer layer BFL. Each of the barrier layers may include polyimide.

On the buffer layer BFL, first to third transistors T_SP1 to T_SP3 corresponding to the first to third sub-pixels SP1 to SP3 may be disposed, respectively. The first transistor T_SP1 may be any one of the transistors of the sub-pixel circuit SPC included in the first sub-pixel SP1. The second transistor T_SP2 may be any one of the transistors of the sub-pixel circuit SPC included in the second sub-pixel SP2. The third transistor T_SP3 may be any one of the transistors of the sub-pixel circuit SPC included in the third sub-pixel SP3. Each of the first to third transistors T_SP1 to T_SP3 may be understood as a transistor connected to the anode electrode among the transistors of the corresponding sub-pixel.

The first transistor T_SP1 may include a semiconductor pattern SCP, a gate electrode GE, a first terminal ET1, and a second terminal ET2. The first terminal ET1 may be either one of the source electrode and the drain electrode, and the second terminal ET2 may be the other one of the source electrode and the drain electrode. For example, the first terminal ET1 may be a source electrode, and the second terminal ET2 may be a drain electrode.

The semiconductor pattern SCP may be disposed on the buffer layer BFL. The semiconductor pattern SCP may include a first contact region contacting the first terminal ET1 and a second contact region contacting the second terminal ET2. A region between the first contact region and the second contact region may be a channel region. The channel region may overlap the gate electrode GE of the first transistor T_SP1. The channel region may be a semiconductor pattern that is not doped with impurities and may be an intrinsic semiconductor. The first contact region and the second contact region may be semiconductor patterns doped with impurities. As an impurity, for example, a p-type impurity may be used, but the embodiments are not limited thereto.

The semiconductor pattern SCP may include any one of various types of semiconductors, for example, an amorphous silicon semiconductor, a monocrystalline silicon semiconductor, a polycrystalline silicon semiconductor, a low temperature poly silicon semiconductor, and an oxide semiconductor.

Interlayer insulating layers ILD may be sequentially stacked on the semiconductor pattern SCP. The interlayer insulating layers ILD may be inorganic insulating layers including inorganic materials. For example, each of the Interlayer insulating layers ILD may include at least one of a metal oxide, such as silicon nitride (SiNₓ), silicon oxide (SiOₓ), silicon oxynitride (SiOₓN_{y}), or aluminum oxide (AlOₓ). However, the interlayer insulating layers ILD are not limited thereto. For example, any one of the Interlayer insulating layers ILD may include an organic dielectric layer including an organic material.

The interlayer insulating layers ILD may electrically isolate conductive patterns and/or semiconductor patterns disposed between the Interlayer insulating layers ILD. For example, the Interlayer insulating layers ILD may include a gate insulating layer GI disposed on the semiconductor pattern SCP. The gate insulating layer GI may be disposed between the semiconductor pattern SCP and the gate electrode GE so that the semiconductor pattern SCP is spaced from the gate electrode GE. In embodiments, the gate insulating layer GI may be provided entirely on the semiconductor pattern SCP and the buffer layer BFL, thereby covering the semiconductor pattern SCP and the buffer layer BFL. As the number of layers required for the conductive patterns and/or semiconductor patterns increases, the number of interlayer insulating layers ILD may increase.

The gate electrode GE may be disposed on the gate insulating layer GI. The gate electrode GE may overlap the channel region of the semiconductor pattern SCP. In embodiments, the gate electrode GE may be provided as a single layer including at least one material selected from copper (Cu), molybdenum (Mo), tungsten (W), aluminum neodymium (AlNd), titanium (Ti), aluminum (Al), and silver (Ag). In embodiments, the gate electrode GE may be provided as a multilayer including at least one of low-resistance materials such as molybdenum (Mo), titanium (Ti), copper (Cu), aluminum (Al), and silver (Ag).

The first and second terminals ET1 and ET2 may be disposed on the interlayer insulating layers ILD. The first and second terminals ET1 and ET2 may contact the semiconductor pattern SCP through contact holes penetrating the interlayer insulating layers ILD. The first and second terminals ET1 and ET2 may contact first and second contact areas of the semiconductor pattern SCP, respectively. Each of the first and second terminals ET1 and ET2 may include at least one material selected from copper (Cu), molybdenum (Mo), tungsten (W), aluminum neodymium (AlNd), titanium (Ti), aluminum (Al), and silver (Ag).

Although the first and second terminals ET1 and ET2 are shown as separate electrodes electrically connected to the semiconductor pattern SCP, embodiments are not limited thereto. In embodiments, the first terminal ET1 may be a first contact region adjacent to one side of a channel region of the semiconductor pattern SCP, and the second terminal ET2 may be a second contact region adjacent to the other side of the channel region. In this case, the first terminal ET1 may be electrically connected to the light emitting element LD via a connection means such as a bridge electrode disposed on at least one of the interlayer insulating layers ILD.

In embodiments, the first transistor T_SP1 may be composed of a low-temperature polysilicon transistor. However, the embodiments are not limited thereto. For example, the first transistor T_SP1 may be composed of an oxide semiconductor transistor. In embodiments, the sub-pixel circuit of each sub-pixel may include different types of transistors. For example, the first transistor T_SP1 may be composed of a low-temperature polysilicon transistor, and the other transistors of the first sub-pixel SP1 may be composed of oxide semiconductor transistors. In this case, the oxide semiconductor of the oxide semiconductor transistor may be disposed on any one of the interlayer insulating layers ILD other than the insulating layer on which the semiconductor pattern SCP of the first transistor T_SP1 is disposed.

In the embodiments, a case where the first transistor T_SP1 is a transistor of a top gate structure has been described as an example, but the embodiments are not limited thereto. For example, the first transistor T_SP1 may be a transistor of a bottom gate structure. The structure of the first transistor T_SP1 may be changed in various ways.

Each of the second and third transistors T_SP2 and T_SP3 may be configured similarly to the first transistor T_SP1. Hereinafter, redundant descriptions may be omitted.

At least some of various wires of the display panel DP and/or the display device DD may be further disposed on the interlayer insulating layers ILD.

A first passivation layer PSV1 may be disposed on the first to third transistors T_SP1 to T_SP3. The passivation layer may also be referred to as a protective layer or a via layer. The first passivation layer PSV1 may protect components disposed thereunder and may provide a flat upper surface.

First to third connection patterns CP1 to CP3 may be disposed on the first passivation layer PSV1. The first to third connection patterns CP1 to CP3 may be connected to the first terminals ET1 of the first to third transistors T_SP1 to T_SP3 respectively by penetrating the first passivation layer PSV1. The first to third connection patterns CP1 to CP3 may include at least one material selected from copper (Cu), molybdenum (Mo), tungsten (W), aluminum neodymium (AlNd), titanium (Ti), aluminum (Al), and silver (Ag).

At least some of the various wires of the display panel DP and/or the display device DD may be further disposed on the first passivation layer PSV1.

A second passivation layer PSV2 may be disposed on the first to third connection patterns CP1 to CP3 and the first passivation layer PSV1. The first passivation layer PSV1 may protect components disposed thereunder and may provide a flat upper surface.

Each of the first and second passivation layers PSV1 and PSV2 may include an inorganic insulating layer including an inorganic material and/or an organic insulating layer including an organic material. The inorganic insulating layer may include at least one of a metal oxide, such as, for example, silicon oxide (SiOₓ), silicon nitride (SiNₓ), silicon oxynitride (SiOₓN_{y}), or aluminum oxide (ALOₓ). The organic insulating layer may include, for example, at least one of an acrylic resin, an epoxy resin, a phenol resin, a polyamide resin, a polyimide resin, an unsaturated polyester resin, a poly-phenylene ether resin, a poly-phenylene sulfide resin, and a benzocyclobutene resin.

The first and second passivation layers PSV1 and PSV2 may include a same material as one of the interlayer insulating layers ILD, but embodiments are not limited thereto. Each of the first and second passivation layers PSV1 and PSV2 may be provided as a single layer, but may also be provided as multiple layers.

The display element layer DPL may be disposed on the second passivation layer PSV2. The display element layer DPL may include first to third anode electrodes AE1 to AE3, a first bank BNK1, first to third light emitting elements LD1_1 to LD3_1, first to third overcoat patterns OCP1 to OCP3, at least one insulating layer INS, a cathode electrode CE, first and second transparent electrode layers ITO1 and ITO2, and a capping layer CPL.

On the pixel circuit layer PCL, the first to third anode electrodes AE1 to AE3 may be respectively disposed on the first to third sub-pixels SP1 to SP3.

The first anode electrode AE1 may be electrically connected to the first connection electrode CP1 through a contact hole penetrating the second passivation layer PSV2. The second anode electrode AE2 may be electrically connected to the second connecting electrode CP2 through another contact hole penetrating the second passivation layer PSV2. The third anode electrode AE3 may be electrically connected to the third connecting electrode CP3 through another contact hole penetrating the second passivation layer PSV2. As such, the first to third anode electrodes AE1 to AE3 may be electrically connected to the first to third transistors T_SP1 to T_SP3, respectively.

The first bank BNK1 may be disposed on the first to third anode electrodes AE1 to AE3. The first bank BNK1 may have first openings OP1 exposing portions of the first to third anode electrodes AE1 to AE3. The first to third light emitting elements LD1_1 to LD3_1 may be disposed in the first openings OP1 of the first bank BNK1. In this way, the first bank BNK1 may be provided as a pixel definition layer that defines areas where the first to third light emitting elements LD1 to LD3 are disposed.

The first bank BNK1 may be configured to include a light shielding material to prevent light mixing between adjacent sub-pixels. In embodiments, the first bank BNK1 may include an organic material. For example, the first bank BNK1 may include an organic insulating material such as an acrylic resin, an epoxy resin, a phenol resin, a polyamide resin, a polyimide resin, and the like within the spirit and the scope of the disclosure.

The first to third reflective electrodes RFE1 to RFE3 may be disposed on exposed portions of the first to third anode electrodes AE1 to AE3. Although not shown in FIG. 7, in order to further improve the light emission efficiency, the first to third reflective electrodes RFE1 to RFE3 may be further disposed to extend to the side surface of the first bank BNK1 adjacent to the first openings OP1. The first to third reflective electrodes RFE1 to RFE3 may include conductive materials suitable for reflecting light. Accordingly, the light emission efficiency of the first to third light emitting elements LD1_1 to LD3_1 may be improved. In embodiments, the first to third reflective electrodes RFE1 to RFE3 may include at least one selected from aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected therefrom. However, the embodiments are not limited thereto.

The first light emitting element LD1_1 may include a first semiconductor layer 11, an active layer 12, a second semiconductor layer 13, and an auxiliary layer 15. The first light emitting element LD1_1 may include a light emitting laminate in which an auxiliary layer 15, a first semiconductor layer 11, an active layer 12, and a second semiconductor layer 13 are sequentially stacked.

The first light emitting element LD1_1 may include a bonding electrode BDE1_1. The bonding electrode BDE1_1 may be adjacent to the first overcoat pattern OCP1 as an end portion opposite to the third direction DR3 of the first light emitting element LD1_1. The first end portion EPT1 of the first light emitting element LD1_1 may refer to a bonding electrode BDE1_1 adjacent to the first overcoat pattern OCP1. For example, the first end portion EPT1 of the first light emitting element LD1_1 may include at least one of a side surface EPT1_SS and a lower surface of the bonding electrode BDE1_1. The bonding electrode BDE1_1 may include a eutectic metal. The bonding electrode BDE1_1 may be connected to the second semiconductor layer 13.

The first semiconductor layer 11 may be configured to provide electrons to the active layer 12. The first semiconductor layer 11 may include, for example, at least one n-type semiconductor layer. For example, the first semiconductor layer 11 may include at least one semiconductor material selected from gallium nitride (GaN), aluminum gallium nitride (AlGaN), indium gallium nitride (InGaN), aluminum nitride (AlN), and indium nitride (InN), and may be an n-type semiconductor layer doped with the first conductive dopant (or n-type dopant) such as silicon (Si), germanium (Ge), tin (Sn), etc. However, the material constituting the first semiconductor layer 11 is not limited thereto, and various other materials may also constitute the first semiconductor layer 11. In an embodiment, the first semiconductor layer 11 may include a gallium nitride (GaN) semiconductor material doped with a first conductive dopant (or n-type dopant). According to an embodiment, the first semiconductor layer 11 may form an n-type semiconductor layer together with the auxiliary layer 15.

The active layer 12 may be a region where electrons and holes recombine. As electrons and holes recombine in the active layer 12, they transition to a lower energy level, and light having a corresponding wavelength may be generated. The active layer 12 may be formed as a single or multiple quantum well structure. In case that the active layer 12 is formed as a multi-quantum well structure, units including a barrier layer, a strain reinforcing layer, and a well layer may be repeatedly stacked to form the active layer 12. However, examples of the active layer 12 are not limited thereto.

The second semiconductor layer 13 may provide holes to the active layer 12. The second semiconductor layer 13 may be spaced apart from the first semiconductor layer 11 with the active layer 12 disposed between the second semiconductor layer 13 and the first semiconductor layer 11. The second semiconductor layer 13 may include a semiconductor layer of a different type from the first semiconductor layer 11. For example, the second semiconductor layer 13 may include at least one p-type semiconductor layer. For example, the second semiconductor layer 13 may include at least one semiconductor material selected from gallium nitride (GaN), aluminum gallium nitride (AlGaN), indium gallium nitride (InGaN), aluminum nitride (AlN), and indium nitride (InN), and may be a p-type semiconductor layer doped with the second conductive dopant (or p-type dopant), such as magnesium (Mg), zinc (Zn), calcium (Ca), strontium (Sr), barium (Ba), etc. However, the material constituting the second semiconductor layer 13 is not limited thereto, and various other materials may also constitute the second semiconductor layer 13. In an embodiment, the second semiconductor layer 13 may include a gallium nitride (GaN) semiconductor material doped with a second conductive dopant (or p-type dopant).

The auxiliary layer 15 may include a gallium nitride (GaN) semiconductor material that is not doped with impurities, and may form an n-type semiconductor layer together with the first semiconductor layer 11. The auxiliary layer 15 may be adjacent to the capping layer CPL as an end portion of the third direction DR3 of the first light emitting element LD1_1. The second end portion EPT2 of the first light emitting element LD1_1 may be spaced apart in a third direction DR3 from the first end portion EPT1 of the first light emitting element LD1_1. The second end portion EPT2 of the first light emitting element LD1_1 may refer to an auxiliary layer 15 adjacent to the capping layer CPL. For example, the second end portion EPT2 of the first light emitting element LD1_1 may include an upper surface of the auxiliary layer 15.

The first light emitting element LD1_1 may further include an insulating film 14 covering a side surface SPT of the light emitting layer. The side surface SPT may be disposed between the first end portion EPT1 and the second end portion EPT2 of the first light emitting element LD1_1. The insulating film 14 may prevent an electrical short circuit that may occur in case that the active layer 12 comes into contact with a conductive material other than the first and second semiconductor layers 11 and 13. The insulating film 14 may include a transparent insulating material. The insulating film 14 may be configured to expose the bonding electrode BDE1_1. The insulating film 14 may be configured to expose the second end portion EPT2.

The first to third overcoat patterns OCP1 to OCP3 may be disposed in the first openings OP1 in which the first to third light emitting elements LD1_1 to LD3_1 are disposed. The first to third overcoat patterns OCP1 to OCP3 may be disposed on the first to third reflective electrodes RFE1 to RFE3. The first to third overcoat patterns OCP1 to OCP3 may fix the first to third light emitting elements LD1_1 to LD3_1 so that they do not move. The first to third overcoat patterns OCP1 to OCP3 may protect the components disposed thereunder from foreign substances such as dust, moisture, or the like within the spirit and the scope of the disclosure. For example, the first to third overcoat patterns OCP1 to OCP3 may include at least one of an inorganic insulating layer and an organic insulating layer. For example, the first to third overcoat patterns OCP1 to OCP3 may include epoxy, but embodiments are not limited thereto.

In embodiments, the first overcoat pattern OCP1 may be disposed between the first end portion EPT1 of the first light emitting element LD1_1 and the first anode electrode AE1. The first overcoat pattern OCP1 may be disposed between the first end portion EPT1 of the first light emitting element LD1_1 and the first reflective electrode RFE1. The first overcoat pattern OCP1 may be in contact with the first end portion EPT1 of the first light emitting element LD1_1. The second overcoat pattern OCP2 may be disposed between the first end portion EPT1 of the second light emitting element LD2_1 and the second anode electrode AE2. The second overcoat pattern OCP2 may be disposed between the first end portion EPT1 of the second light emitting element LD2_1 and the second reflective electrode RFE2. The second overcoat pattern OCP2 may be in contact with the first end portion EPT1 of the second light emitting element LD2_1. The third overcoat pattern OCP3 may be disposed between the first end portion EPT1 of the third light emitting element LD3_1 and the third anode electrode AE3. The third overcoat pattern OCP3 may be disposed between the first end portion EPT1 of the third light emitting element LD3_1 and the third anode electrode AE3. The third overcoat pattern OCP3 may be in contact with the first end portion EPT1 of the third light emitting element LD3_1.

The first transparent electrode layer ITO1 may be disposed on the first to third overcoat patterns OCP1 to OCP3. The first transparent electrode layer ITO1 may be in contact with the first to third overcoat patterns OCP1 to OCP3. The first transparent electrode layer ITO1 may be in contact with portions of the first to third anode electrodes AE1 to AE3 exposed by the first openings OP1. The first transparent electrode layer ITO1 may be in contact with the first end portion EPT1 of each of the first to third light emitting elements LD1_1 to LD3_1. For example, the first transparent electrode layer ITO1 may be in contact with the side surface EPT1_SS of each of the bonding electrodes BDE1_1 to BDE3_1. The first transparent electrode layer ITO1 may also be in contact with a portion of a side surface SPT disposed between the first end portion EPT1 and the second end portion EPT2 of each of the first to third light emitting elements LD1_1 to LD3_1.

The first transparent electrode layer ITO1 may electrically connect the first end portion EPT1 of the first light emitting element LD1_1 and the first anode electrode AE1. The first transparent electrode layer ITO1 may electrically connect the first end portion EPT1 of the second light emitting element LD2_1 and the second anode electrode AE2. The first transparent electrode layer ITO1 may electrically connect the first end portion EPT1 of the third light emitting element LD3_1 and the third anode electrode AE3. For example, the bonding electrodes BDE1_1 to BDE3_1 may be electrically connected to the first to third anode electrodes AE1 to AE3 through the first transparent electrode layer ITO1 in contact with a side surface EPT1_SS of each thereof.

In embodiments, the first transparent electrode layer ITO1 may be configured to be substantially transparent or translucent to satisfy a selectable light transmittance. In embodiments, the first transparent electrode layer ITO1 may include at least one selected from various transparent conductive materials, such as indium tin oxide (ITO), indium zinc oxide (IZO), zinc oxide (ZnO), indium gallium zinc oxide (IGZO), indium tin zinc oxide (ITZO), and the like within the spirit and the scope of the disclosure. However, the material of the first transparent electrode layer ITO1 is not limited thereto.

At least one insulating layer INS may be disposed on the first bank BNK1 and the first transparent electrode layer ITO1. At least one insulating layer INS may protect components disposed thereunder and provide a flat top surface. At least one insulating layer INS may include a same material as either one of the first and second passivation layers PSV1 and PSV2, but embodiments are not limited thereto.

At least one insulating layer INS may include a first insulating layer INS1 and a second insulating layer INS2. The first insulating layer INS1 may be disposed on each of the first to third anode electrodes AE1 to AE3 and the cathode electrode CE (see FIG. 6). The second insulating layer INS2 may be disposed on the first insulating layer INS1. For example, the first insulating layer INS1 may be in contact with the first transparent electrode layer ITO1. The second insulating layer INS2 may be in contact with the side surface SPT of each of the first to third light emitting elements LD1_1 to LD3_1.

In this way, by forming the first insulating layer INS1 on the first to third anode electrodes AE1 to AE3, the bonding reliability of the first to third light emitting elements LD1_1 to LD3_1 may be improved. By way of example, in case that bonding the first to third light emitting elements LD1_1 to LD3_1 on the first to third overcoat patterns OCP1 to OCP3, freer alignment may be possible.

In embodiments, at least one insulating layer INS may not overlap the first to third light emitting elements LD1_1 to LD3_1. The first to third light emitting elements LD1_1 to LD3_1 may protrude into the light functional layer LFL. The first to third light emitting elements LD1_1 to LD3_1 may be at least partially disposed in the second openings OP2 of the second bank BNK2. For example, a height of the second end portion EPT2 of each of the first to third light emitting elements LD1_1 to LD3_1 from the substrate SUB may be higher than the lowermost end portion RBE of the reflective layer RFL. Accordingly, light emitted from the first to third light emitting elements LD1_1 to LD3_1 may be provided to the light functional layer LFL at a relatively high ratio.

The second transparent electrode layer ITO2 may be disposed on at least one insulating layer INS. The second transparent electrode layer ITO2 may be spaced apart from the first transparent electrode layer ITO1 in the third direction DR3 with at least one insulating layer INS disposed between the second transparent electrode layer ITO2 and the first transparent electrode layer ITO1. The second transparent electrode layer ITO2 may be in contact with the second insulating layer INS2.

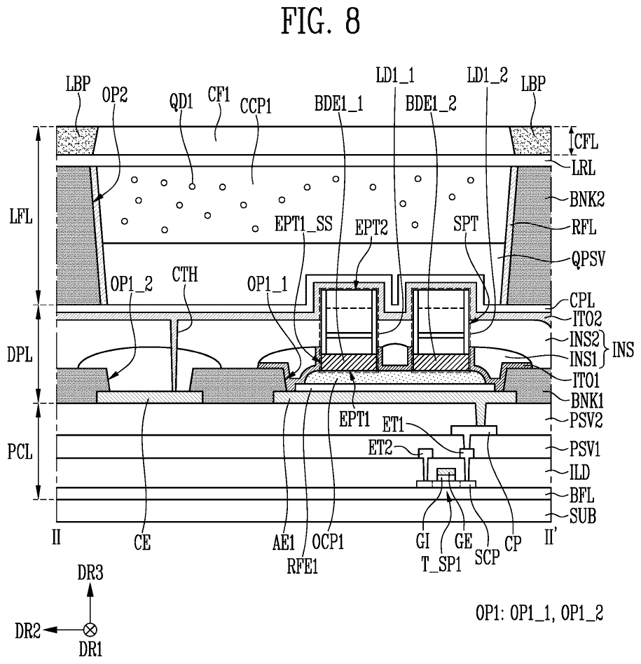

The second transparent electrode layer ITO2 may be disposed on the first to third light emitting elements LD1_1 to LD3_1. The second transparent electrode layer ITO2 may be in contact with the second end portion EPT2 of each of the first to third light emitting elements LD1_1 to LD3_1. The second transparent electrode layer ITO2 may be connected to the cathode electrode CE through a contact hole CTH (see FIG. 8) penetrating at least one insulating layer INS. The second transparent electrode layer ITO2 may electrically connect the second end portion EPT2 of each of the first to third light emitting elements LD1_1 to LD3_1 and the cathode electrode CE. For example, the auxiliary layer 15 of each of the first to third light emitting elements LD1_1 to LD3_1 may be electrically connected to the cathode electrode CE through the second transparent electrode layer ITO2 connected to the upper surface of the auxiliary layer 15. Accordingly, the first to third light emitting elements LD1_1 to LD3_1 may be electrically connected between the first to third anode electrodes AE1 to AE3 and the cathode electrode CE, respectively.

In embodiments, the second transparent electrode layer ITO2 may be configured to be substantially transparent or translucent to satisfy a selectable light transmittance. In embodiments, the second transparent electrode layer ITO2 may include a same material as the first transparent electrode layer ITO1, but the embodiments are not limited thereto.

The remaining first to third light emitting elements LD1_2 to LD3_2 of FIG. 6 may also be configured similarly to the first to third light emitting elements LD1_1 to LD3_1 of FIG. 7.

The capping layer CPL may be disposed on the second transparent electrode layer ITO2. The capping layer CPL may protect components under or below the capping layer CPL, such as the first and second transparent electrode layers ITO1 and ITO2, and the first to third light emitting elements LD1_1 to LD3_1, from external moisture and humidity. The capping layer CPL may include at least one selected from silicon nitride (SiNₓ), silicon oxide (SiOₓ), silicon oxynitride (SiOₓN_{y}), and a metal oxide such as aluminum oxide (ALOₓ). However, the material of the capping layer CPL is not limited thereto.

The light functional layer LFL may be disposed on the capping layer CPL. The light functional layer LFL may include a second bank BNK2, a reflective layer RFL, a third passivation layer PSV3, first and second light conversion patterns CCP1 and CCP2, a light scattering pattern LSP, a low refractive layer LRL, and a color filter layer CFL.

The second bank BNK2 may be disposed on the capping layer CPL. The second bank BNK2 may overlap the first bank BNK1. The second bank BNK2 may have second openings OP2 overlapping the first openings OP1.

The second bank BNK2 may be configured to include a light shielding material to prevent light mixing between adjacent pixels and the first to third sub-pixels SP1 to SP3. In embodiments, the second bank BNK2 may include an organic material. For example, the second bank BNK2 may include an organic insulating material such as an acrylic resin, an epoxy resin, a phenol resin, a polyamide resin, or a polyimide resin.

The reflective layer RFL may be disposed on side surfaces of the second bank BNK2 adjacent to the second openings OP2. The reflective layer RFL may be configured to reflect incident light, thereby improving light emission efficiency. The reflective layer RFL may include a material suitable for reflecting light. The reflective layer RFL may include at least one selected from aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom. However, the embodiments are not limited thereto.

It may be understood that the emitting area EMA and the non-emitting area NEMA for the first to third sub-pixels SP1 to SP3 are defined by the second bank BNK2. An area overlapping the second bank BNK2 may correspond to the non-emitting area NEMA. An area overlapping the second openings OP2 of the second bank BNK2 may correspond to the emitting area EMA.

On the capping layer CPL, a third passivation layer PSV3 may be disposed in the second openings OP2. The third passivation layer PSV3 protects the components disposed thereunder and may provide a flat upper surface. The third passivation layer PSV3 may include a same material as either of the first and second passivation layers PSV1 and PSV2, but embodiments are not limited thereto.

On the third passivation layer PSV3, first and second light conversion patterns CCP1 and CCP2 and a light scattering pattern LSP may be disposed in the second openings OP2.

The first and second light conversion patterns CCP1 and CCP2 and the light scattering pattern LSP may include color conversion particles and/or scattering particles. The color conversion particles may convert incident light into light of a different color by changing a wavelength of the incident light. The color conversion particles may scatter the incident light. In embodiments, the color converting particles may be quantum dots. The scattering particles may scatter the incident light.

In embodiments, the first to third light emitting elements LD1_1 to LD3_1 may be configured to emit blue color light. In this case, the first light conversion pattern CCP1 may include first color conversion particles QD1 configured to convert blue color light into red color light. The second light conversion pattern CCP2 may include second color conversion particles QD2 configured to convert blue color light into green color light. The light scattering pattern LSP may include scattering particles SCT that scatter blue light to improve the light emission efficiency. Accordingly, the first to third sub-pixels SP1 to SP3 may be provided as red sub-pixels, green sub-pixels, and blue sub-pixels, respectively. In embodiments, at least one of the first and second light conversion patterns CCP1 and CCP2 and the light scattering pattern LSP may further include color conversion particles that convert blue color light into white color light.

In embodiments, the first to third light emitting elements LD1_1 to LD3_1 may be configured to emit red color light, green color light, and blue color light, respectively. In this case, each of the first and second light conversion patterns CCP1 and CCP2 and the light scattering pattern LSP may include scattering particles SCT. In this way, particles included in the first and second light conversion patterns CCP1 and CCP2 and the light scattering pattern LSP may be variously changed depending on the first to third light emitting elements LD1_1 to LD3_1.

In embodiments, the first and second light conversion patterns CCP1 and CCP2 and the light scattering pattern LSP may be omitted.

The low refractive layer LRL may be disposed on the second bank BNK2, the reflective layer RFL, the first light conversion pattern CCP1, the second light conversion pattern CCP2, and the light scattering pattern LSP. The low refractive layer LRL may have a lower refractive index than the first and second light conversion patterns CCP1 and CCP2 and the light scattering pattern LSP. The low refractive layer LRL may be configured to refract or totally reflect light depending on an angle of incidence of the light. The low refractive layer LRL may provide light that has passed through the first and second light conversion patterns CCP1 and CCP2 and the light scattering pattern LSP back to the first and second light conversion patterns CCP1 and CCP2 and the light scattering pattern LSP. Accordingly, the light conversion efficiency and light scattering efficiency of the first and second light conversion patterns CCP1 and CCP2 and the light scattering pattern LSP may be improved. In embodiments, the low refractive layer LRL may be omitted in an area corresponding to the third sub-pixel SP3.

The color filter layer CFL may be disposed on the low refractive layer LRL. The color filter layer CFL may include first to third color filters CF1 to CF3 and light blocking patterns LBP.

The first to third color filters CF1 to CF3 may overlap the first and second light conversion patterns CCP1 and CCP2 and the light scattering pattern LSP, respectively. Each of the first to third color filters CF1 to CF3 may selectively transmit light of a desired wavelength range. In case that the first sub-pixel SP1 is a red sub-pixel, the first color filter CF1 may include a red color filter. In case that the second sub-pixel SP2 is a green sub-pixel, the second color filter CF2 may include a green color filter. In case that the third sub-pixel SP3 is a blue sub-pixel, the third color filter CF3 may include a blue color filter. The first to third color filters CF1 to CF3 may have a higher refractive index than the low refractive layer LRL. However, embodiments are not limited thereto, and the first to third color filters CF1 to CF3 may have a refractive index lower than or equal to the low refractive layer LRL.

Light blocking patterns LBP may be disposed between the first to third color filters CF1 to CF3. It may be understood that the emitting area (or light emitting area) EMA and the non-emitting area NEMA for the first to third sub-pixels SP1 to SP3 are defined by the light blocking patterns LBP. An area overlapping the light blocking patterns LBP may correspond to the non-emitting area NEMA. An area that does not overlap the light blocking patterns LBP may correspond to the emitting area EMA.

In embodiments, the light blocking patterns LBP may include at least one of various types of light shielding materials. In embodiments, each of the light blocking patterns LBP may be provided in the form of a multilayer in which at least two color filters among the first to third color filters CF1 to CF3 overlap. For example, each of the light blocking patterns LBP may be formed by overlapping first to third color filters CF1 to CF3. For another example, the light blocking pattern between the first and second color filters CF1 and CF2 among the light blocking patterns LBP may be formed as a multilayer in which the first and second color filters CF1 and CF2 overlap, and the light blocking pattern between the second and third color filters CF2 and CF3 among the light blocking patterns LBP may be formed as a multilayer in which the second and third color filters CF2 and CF3 overlap. The light blocking pattern between the first color filter CF1 and the third color filter CF3 of a pixel neighboring thereto may be formed as a multilayer in which the first and third color filters CF1 and CF3 overlap. In this way, each of the first to third color filters CF1 to CF3 may extend into the non-emitting area NEMA to form light blocking patterns LBP.

FIG. 8 is a schematic cross-sectional view taken along line II-II′ of FIG. 6.

Referring to FIGS. 6 and 8, the pixel circuit layer PCL, the display element layer DPL, and the light function layer LFL may be sequentially provided on the substrate SUB.

The pixel circuit layer PCL and the display element layer DPL are described in the same manner as described with reference to FIG. 7. In the pixel circuit layer PCL, sub-pixel circuits corresponding to the first to third sub-pixels SP1 to SP3 may be provided, respectively. In the display element layer DPL, at least one first light emitting element LD1_1 and LD1_2 corresponding to the first sub-pixel SP1 may be provided. The first light emitting elements LD1_1 and LD1_2 may overlap any one of the first openings OP1 of the first bank BNK1. The first light emitting elements LD1_1 and LD1_2 may be connected between the cathode electrode CE and a transistor T_SP1 included in the sub-pixel circuit of the first sub-pixel SP1. Hereinafter, redundant descriptions may be omitted.

The light function layer LFL may be provided on the display element layer DPL. The light functional layer LFL is described in the same manner as described with reference to FIG. 7. Hereinafter, redundant descriptions may be omitted.

The first anode electrode AE1 and the cathode electrode CE may be disposed in the same layer on the substrate SUB. The first anode electrode AE1 and the cathode electrode CE may be spaced apart from each other in the second direction DR2.

In embodiments, the first anode electrode AE1 may be electrically connected to the first light emitting elements LD1_1 and LD1_2 through the first transparent electrode layer ITO1. For example, the first anode electrode AE1 may overlap any one OP1_1 of the first openings OP1 of the first bank BNK1. A portion of the first anode electrode AE1 may be exposed through the one OP1_1 of the first openings OP1 of the first bank BNK1. A portion of the first anode electrode AE1 and the first transparent electrode layer ITO1 may be in contact with each other in the one OP1_1 of the first openings OP1 of the first bank BNK1.

The first transparent electrode layer ITO1 may be disposed on the first anode electrode AE1. The first transparent electrode layer ITO1 connected to the first anode electrode AE1 may be disposed on the first overcoat pattern OCP1. The first transparent electrode layer ITO1 may be in contact with the first end portion EPT1 and the first overcoat pattern OCP1 of each of the first light emitting elements LD1_1 and LD1_2. The first transparent electrode layer ITO1 may be in contact with the bonding electrodes BDE1_1 and BDE1_2 of the first light emitting elements LD1_1 and LD1_2. For example, the first transparent electrode layer ITO1 may be in contact with side surfaces of the bonding electrodes BDE1_1 and BDE1_2 of the first light emitting elements LD1_1 and LD1_2. The first anode electrode AE1 may be electrically connected to the transistor T_SP1. A voltage applied from the first power voltage node VDDN through the transistor T_SP1 may be transmitted to the first light emitting elements LD1_1 and LD1_2 through the first transparent electrode layer ITO1.

The cathode electrode CE may be electrically connected to the first light emitting elements LD1_1 and LD1_2 through the second transparent electrode layer ITO2. For example, the cathode electrode CE may overlap another one OP1_2 of the first openings OP1 of the first bank BNK1. A portion of the cathode electrode CE may be exposed through another one OP1_2 of the first openings OP1 of the first bank BNK1. The cathode electrode CE and the second transparent electrode layer ITO2 may be connected through a contact hole CTH in another one OP1_2 of the first openings OP1 of the first bank BNK1. For example, the contact hole CTH may penetrate at least one insulating layer INS and overlap the cathode electrode CE. The contact hole CTH may be spaced apart from the first light emitting elements LD1_1 and LD1_2 in the second direction DR2 without overlapping the first light emitting elements LD1_1 and LD1_2.

The first transparent electrode layer ITO1 and the second transparent electrode layer ITO2 may be disposed in different layers on the substrate SUB. The first transparent electrode layer ITO1 and the second transparent electrode layer ITO2 may be spaced apart from each other in the third direction DR3. The first transparent electrode layer ITO1 and the second transparent electrode layer ITO2 may be spaced apart from each other with at least one insulating layer INS disposed between the first transparent electrode layer ITO1 and the second transparent electrode layer ITO2.

The second transparent electrode layer ITO2 may be disposed on the first light emitting elements LD1_1 and LD1_2. The second transparent electrode layer ITO2 connected to the cathode electrode CE may be entirely disposed on the first bank BNK1, the first light emitting elements LD1_1 and LD1_2, and at least one insulating layer INS. The second transparent electrode layer ITO2 may be in contact with the second end portion EPT2 of each of the first light emitting elements LD1_1 and LD1_2. The second transparent electrode layer ITO2 may be in contact with the auxiliary layer 15 (see FIG. 7) of each of the first light emitting elements LD1_1 and LD1_2. For example, the second transparent electrode layer ITO2 may be in contact with the upper surface of the auxiliary layer 15 (see FIG. 7) of each of the first light emitting elements LD1_1 and LD1_2. The cathode electrode CE may be electrically connected to the second power voltage node VSSN of FIG. 2. The second power voltage applied to the second power voltage node VSSN may be transmitted to the first light emitting elements LD1_1 and LD1_2 through the second transparent electrode layer ITO2.

As described above, the display element layer DPL of the first sub-pixel SP1 is described. Each of the second and third sub-pixels SP2 and SP3 of FIG. 6 may also be configured similarly to the first sub-pixel SP1, to the extent not otherwise described herein.

It is assumed that one end portion of the first light emitting element is connected to the first anode electrode AE1 through the first transparent electrode layer ITO1, and the other end portion of the first light emitting element is connected to the cathode electrode CE through the third transparent electrode layer disposed in the same layer as the first transparent electrode layer ITO1 without the contact hole CTH. In this case, a distance between the first transparent electrode layer ITO1 and the third transparent electrode layer may be relatively close, which may cause a short between the first transparent electrode layer ITO1 and the third transparent electrode layer. For example, the first transparent electrode layer ITO1 and the third transparent electrode layer may be formed using the same photoresist during the manufacturing process, and a portion of the photoresist may be left behind without being removed. In case that the left photoresist exists between the first transparent electrode layer ITO1 and the third transparent electrode layer, the first transparent electrode layer ITO1 and the third transparent electrode layer will be unintentionally electrically connected. As the distance between the first transparent electrode layer ITO1 and the third transparent electrode layer becomes closer, the possibility of the first transparent electrode layer ITO1 and the third transparent electrode layer being short-circuited may increase. This means that the first anode electrode AE1 and the cathode electrode CE are unintentionally short-circuited, and thus the operational reliability of the display device may be relatively low.

According to an embodiment, the second end portion EPT2 of each of the first light emitting elements LD1_1 and LD1_2 may be disposed to face in the opposite direction to the substrate SUB and may be connected to the cathode electrode CE through the second transparent electrode layer ITO2 and the contact hole CTH. For example, a transparent electrode layer disposed on the same layer as the first transparent electrode layer ITO1 and connecting the first light emitting elements LD1_1 and LD1_2 to the cathode electrode CE may not be provided. Accordingly, unintentional short-circuiting of the first anode electrode AE1 and the cathode electrode CE is prevented, and thus the display device may have improved operational reliability.

The first transparent electrode layer ITO1 connected to the first anode electrode AE1 may be disposed to surround side surfaces of the first end portion EPT1 of each of the first light emitting elements LD1_1 and LD1_2, and the second transparent electrode layer ITO2 connected to the cathode electrode CE may be disposed on the upper surface of the second end portion EPT1 of each of the first light emitting elements LD1_1 and LD1_2. Accordingly, the first transparent electrode layer ITO1 can be formed entirely on the side surfaces of the first end portion EPT1 of each of the first light emitting elements LD1_1 and LD1_2, thereby increasing a contact area between the first transparent electrode layer ITO1 connected to the first anode electrode AE1 and the first light emitting elements LD1_1 and LD1_2. Therefore, the display device may have improved stability.

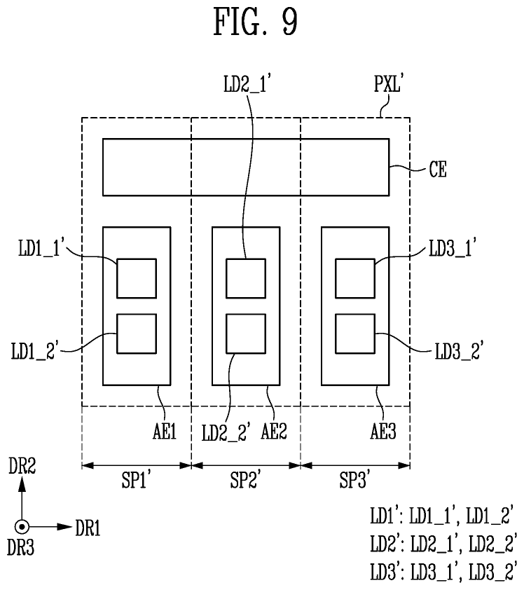

FIG. 9 is a schematic plan view showing an embodiment of one of pixels of FIG. 3.

Referring to FIG. 9, the first pixel PXL′ may include first to third sub-pixels SP1′ to SP3′. Hereinafter, descriptions overlapping that of FIG. 6 may be omitted.

The first to third sub-pixels SP1′ to SP3′ may be arranged in the first direction DR1. First to third anode electrodes AE1′ to AE3′ may be respectively disposed in the first to third sub-pixels SP1′ to SP3′. A cathode electrode CE may be disposed in the first to third sub-pixels SP1′ to SP3′ spaced apart from the first to third anode electrodes AE1′ to AE3′ in the second direction DR2. In other embodiments, first to third anode electrodes AE1 to AE3 may be represented by first to third anode electrodes AE1′ to AE3′ and first to third anode electrodes AE1″ to AE3″.

On the first to third anode electrodes AE1′ to AE3′, one or more first light emitting elements LD1_1′ and LD1_2′, one or more second light emitting elements LD2_1′ and LD2_2′, and one or more third light emitting elements LD3_1′ and LD3_2′ may be disposed.

The first light emitting elements LD1′ may be connected to the first anode electrode AE1′. The second light emitting elements LD2′ may be connected to the second anode electrode AE2′. The third light emitting elements LD3′ may be connected to the third anode electrode AE3′. In this way, the first to third anode electrodes AE1′ to AE3′ may have a shape extending in the second direction DR2. Two light emitting elements may be arranged in the second direction DR2 on each of the first to third anode electrodes AE1′ to AE3′.

On the first to third anode electrodes AE1′ to AE3′, the first to third light emitting elements LD1′ to LD3′ may have polygonal shapes when viewed in the third direction DR3. For example, the first to third light emitting elements LD1′ to LD3′ may have square shapes as shown in FIG. 9. However, the embodiments are not limited thereto.

The shapes of the first to third light emitting elements LD1′ to LD3′ shown in FIGS. 6 and 9 are examples, and the embodiments are not limited thereto. Each anode electrode may include one or more light emitting elements, each of the light emitting elements may have various shapes and sizes.

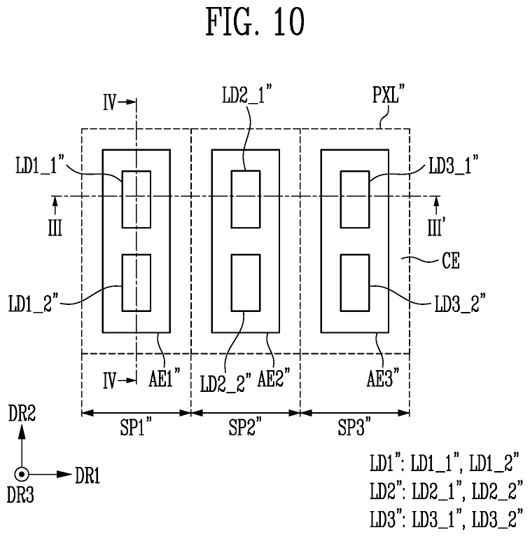

FIG. 10 is a schematic plan view showing an embodiment of one of pixels of FIG. 3.

Referring to FIG. 10, a pixel PXL″ may include first to third sub-pixels SP1″ to SP3″. The first to third sub-pixels SP1″ to SP3″ may be arranged in the first direction DR1. The pixel PXL″ may include first to third anode electrodes AE1″ to AE3″, a cathode electrode CE″, and first to third light emitting elements LD1″ to LD3″.

The first to third anode electrodes AE1″ to AE3″ may be described in the same manner as the embodiments of FIG. 6. Hereinafter, overlapping descriptions with respect to the embodiments of FIG. 6 may be omitted, and differences from the above-described embodiments will be described.

On the first to third anode electrodes AE1″ to AE3″, the first to third light emitting elements LD1″ to LD3″ may have rectangular shapes when viewed in the third direction DR3. For example, in case that the first to third light emitting elements LD1″ to LD3″ have a rectangular shape, one pair of sides extending in the second direction DR2 may be longer than the other pair of sides extending in the first direction DR1. However, the embodiments are not limited thereto.

The cathode electrode CE″ may be disposed on the first to third light emitting elements LD1″ to LD3″. The cathode electrode CE″ may be disposed spaced apart from the first to third anode electrodes AE1″ to AE3″ in the third direction DR3.

The cathode electrode CE″ may be extended in the second direction DR2 as well as the first direction DR1 when viewed in the third direction DR3 and may be disposed entirely in the first to third sub-pixels SP1″ to SP3″. For example, a portion of the cathode electrode CE″ may overlap the first to third anode electrodes AE1″ to AE3″ and the first to third light emitting elements LD1″ to LD3″. Another portion of the cathode electrode CE″ may not overlap the first to third anode electrodes AE1″ to AE3″ and the first to third light emitting elements LD1″ to LD3″.

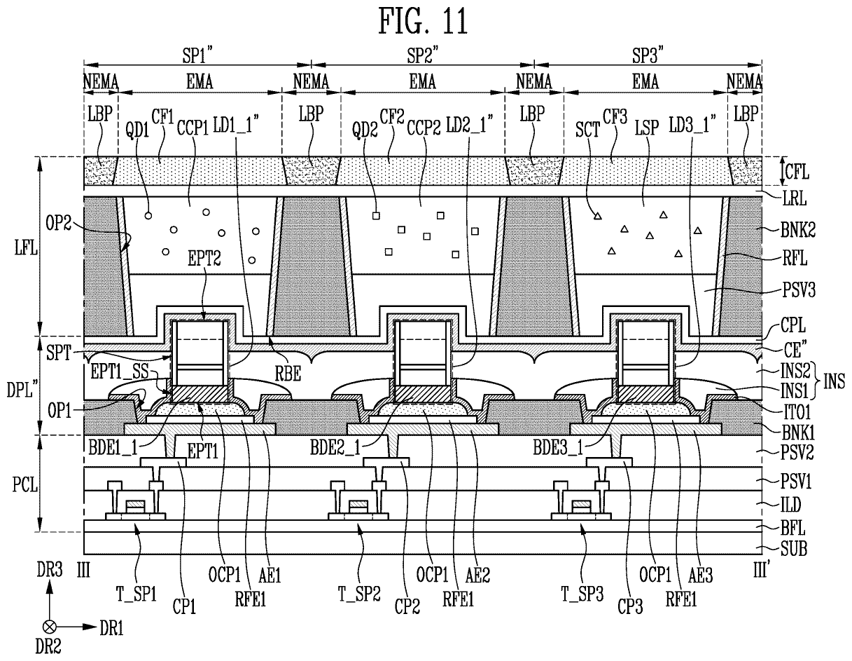

FIG. 11 is a schematic cross-sectional view taken along line III-III′ of FIG. 10.

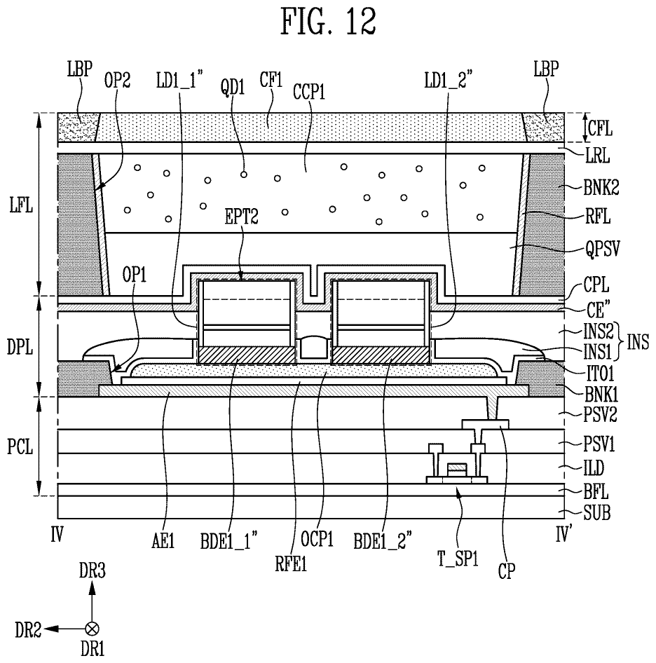

FIG. 12 is a schematic cross-sectional view taken along line IV-IV′ of FIG. 10.

Referring to FIGS. 10, 11, and 12, a pixel circuit layer PCL, a display element layer DPL″, and a light function layer LFL may be sequentially provided on the substrate SUB.

The pixel circuit layer PCL and the light function layer LFL may be described in the same manner as described with reference to FIGS. 7 and 8. The first to third anode electrodes AE1 to AE3, the first to third reflective electrodes RFE1 to RFE3, the first to third overcoat patterns OCP1 to OCP3, the first transparent electrode layer ITO1, the first to third light emitting elements LD1_1″ to LD3_1″, and at least one insulating layer INS may be described similarly to the embodiments of FIGS. 7 and 8. Hereinafter, overlapping descriptions with respect to the embodiments of FIGS. 7 and 8 may be omitted, and differences from the above-described embodiments will be described.

Referring to FIGS. 10 and 11, a cathode electrode CE″ may be disposed on at least one insulating layer INS. The cathode electrode CE″ may be spaced apart from the first to third anode electrodes AE1 to AE3 in the third direction DR3. The cathode electrode CE″ may be spaced apart in the third direction DR3 from the first transparent electrode layer ITO1 with at least one insulating layer INS disposed between the cathode electrode CE″ and the first transparent electrode layer ITO1. The cathode electrode CE″ may be entirely disposed on the second insulating layer INS2 and may be in contact with the second insulating layer INS2.

The cathode electrode CE″ may be disposed on the first to third light emitting elements LD1_1″ to LD3_1″. The cathode electrode CE″ may be in contact with the second end portion EPT2 of each of the first to third light emitting elements LD1_1″ to LD3_1″. The cathode electrode CE″ and the second end portion EPT2 of each of the first to third light emitting elements LD1_1″ to LD3_1″ may be electrically connected. Accordingly, the auxiliary layer 15 of each of the first to third light emitting elements LD1_1″ to LD3_1″ may be electrically connected to the cathode electrode CE″.

The cathode electrode CE″ may be configured to be substantially transparent or translucent to satisfy a selectable light transmittance. In embodiments, the cathode electrode CE″ may include at least one selected from various transparent conductive materials, such as indium tin oxide (ITO), indium zinc oxide (IZO), zinc oxide (ZnO), indium gallium zinc oxide (IGZO), indium tin zinc oxide (ITZO), and the like within the spirit and the scope of the disclosure. However, the material of the cathode electrode CE″ is not limited thereto.

Referring to FIG. 10 and FIG. 12, the first anode electrode AE1 and the cathode electrode CE″ may be disposed in different layers on the substrate SUB. The first anode electrode AE1 and the cathode electrode CE″ may be spaced apart from each other in the third direction DR3.

The cathode electrode CE″ may be disposed on the first light emitting elements LD1_1″ and LD1_2 and electrically connected thereto. The cathode electrode CE″ may be entirely disposed on the first bank BNK1, the first light emitting elements LD1_1″ and LD1_2, and at least one insulating layer INS. For example, the cathode electrode CE″ may overlap the first light emitting elements LD1_1″ and LD1_2 disposed in the first openings OP1 of the first bank BNK1. The cathode electrode CE″ may be directly disposed on the first light emitting elements LD1_1″ and LD1_2 and may be in contact with the second end portion EPT2 of each of the first light emitting elements LD1_1″ and LD1_2. The cathode electrode CE″ may be in contact with the upper surface of each of the first light emitting elements LD1_1″ and LD1_2. For example, the cathode electrode CE″ may be in contact with the auxiliary layer 15 of each of the first light emitting elements LD1_1″ and LD1_2.

As described above, the display element layer DPL of the first sub-pixel SP1″ is described. Each of the second and third sub-pixels SP2″ and SP3″ of FIG. 11 may also be configured similarly to the first sub-pixel SP1″, to the extent not otherwise described herein.

In this way, in case that the first to third light emitting elements LD1_1″ to LD3_1″ have a relatively large size, the first transparent electrode layer ITO1 connected to the first to third anode electrodes AE1 to AE3 may be formed to be in contact with the first end portion EPT1 of the first to third light emitting elements LD1_1″ to LD3_1″, and the cathode electrode CE″ may be formed to be in contact with the second end portion EPT2 of the first to third light emitting elements LD1_1″ to LD3_1″, thereby increasing an integration area and improving an integration degree.

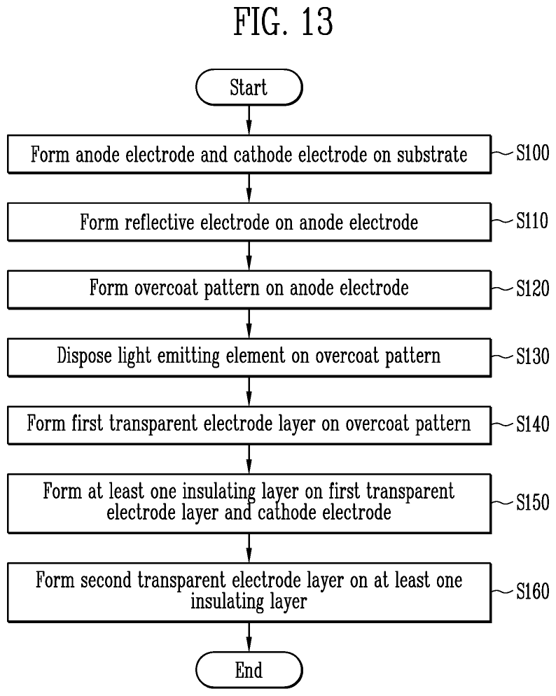

FIG. 13 is a flowchart showing a manufacturing method of a display device according to an embodiment.

Referring to FIG. 13, a manufacturing method of a display device DD according to an embodiment may include forming an anode electrode and a cathode electrode on a substrate (S100), forming a reflective electrode on the anode electrode (S110), forming an overcoat pattern on the anode electrode (S120), disposing a light emitting element on the overcoat pattern (S130), forming a first transparent electrode layer on the overcoat pattern (S140), forming at least one insulating layer on the first transparent electrode layer and the cathode electrode (S150), and forming a second transparent electrode layer on the at least one insulating layer (S160).

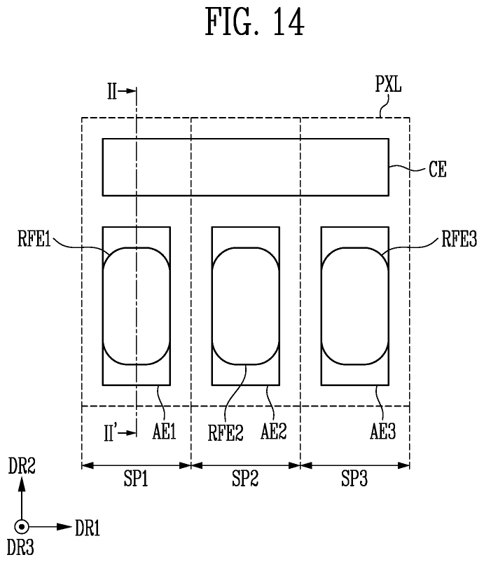

FIGS. 14 to 23 are drawings showing an example of a manufacturing method of a display device of FIG. 13.

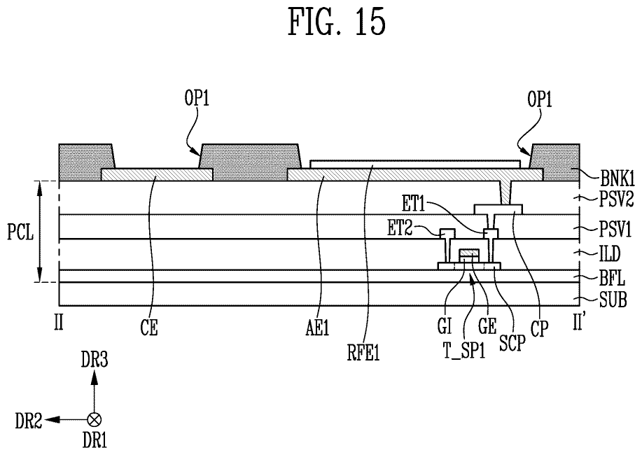

FIG. 14 is a schematic plan view of a display devices in S100 and S110 of FIG. 13. FIG. 15 is a schematic cross-sectional view taken along line II-II′ of FIG. 14.

Hereinafter, it is understood that line II-II′ of each of FIGS. 14, 16, 18, 20 and 21 is a cutting plane line for the same position as line II-II′ of FIG. 6.

Referring to FIGS. 13, 14 and 15, in S100, the first to third anode electrodes AE1 to AE3 and the cathode electrode CE may be formed on the substrate SUB (or pixel circuit layer PCL).

According to an embodiment, the pixel circuit layer PCL on the substrate SUB may be formed based on a given process for manufacturing a semiconductor device. For example, a conductive layer or an insulating layer included in the pixel circuit layer PCL may be formed by a photolithography process. By way of example, the conductive layer or insulating layer included in the pixel circuit layer PCL may be etched by various methods (wet etching, dry etching, etc.) and deposited by various methods (sputtering, chemical vapor deposition, etc.). However, the embodiments are not limited thereto.

A first transistor T_SP1 may be formed on the substrate SUB, and a buffer layer BFL, interlayer insulating layers ILD, a first passivation layer PSV1, and a second passivation layer PSV2 may be formed on the substrate SUB.

The first transistor T_SP1 may be any one of the transistors of the sub-pixel circuit included in the first sub-pixel SP1. The first transistor T_SP1 may include a semiconductor pattern SCP, a gate electrode GE, a first terminal ET1, and a second terminal ET2. A gate insulating layer GI may be disposed between the semiconductor pattern SCP and the gate electrode GE. The first transistor T_SP1 may be electrically connected to the first anode electrode AE1 through a connection pattern CP.

The cathode electrode CE may be formed on the pixel circuit layer PCL. For example, the cathode electrode CE may be formed to extend in the first direction DR1 and cover the first to third sub-pixels SP1 to SP3.

The first to third anode electrodes AE1 to AE3 may be formed on the pixel circuit layer PCL. For example, the first to third anode electrodes AE1 to AE3 may be formed spaced apart from the cathode electrode CE in the second direction DR2. For example, the first to third anode electrodes AE1 to AE3 may be formed to be spaced apart from each other in the first direction DR1 and isolated from each other.

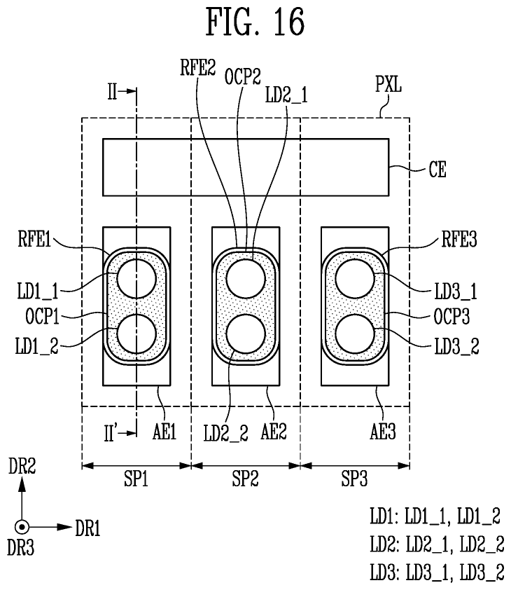

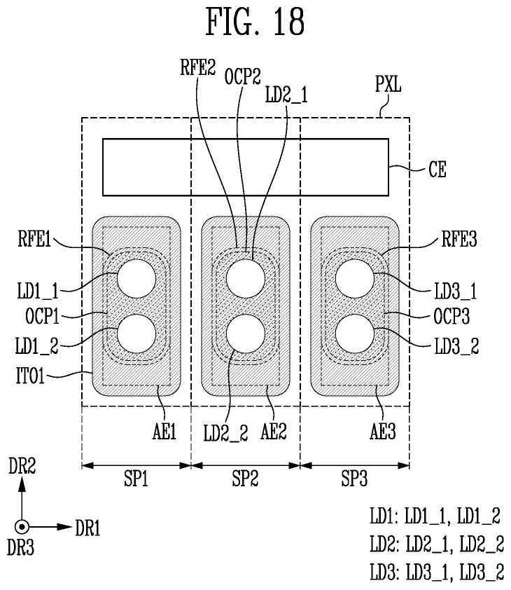

According to an embodiment, areas where the first to third anode electrodes AE1 to AE3 are formed may correspond to areas where the first to third light emitting elements LD1 to LD3 (see FIG. 16), the overcoat patterns OCP1 to OCP3 (see FIG. 16), and the first transparent electrode layer ITO1 (see FIG. 18) are disposed in subsequent processes.

The bank BNK1 may be formed on the substrate SUB. For example, the bank BNK1 may have first openings OP1 formed to surround each of two or more areas. The first openings OP1 may expose a portion of the cathode electrode CE and a portion of each of the first to third anode electrodes AE1 to AE3.

In S110, first to third reflective electrodes RFE1 to RFE3 may be formed on the substrate SUB (or pixel circuit layer PCL).

According to an embodiment, the first to third reflective electrodes RFE1 to RFE3 may be formed by a photolithography process. By way of example, the first to third reflective electrodes RFE1 to RFE3 may be etched by various methods (wet etching, dry etching, etc.) and deposited by various methods (sputtering, chemical vapor deposition, etc.). However, the embodiments are not limited thereto.

The first to third reflective electrodes RFE1 to RFE3 may be formed on the first to third anode electrodes AE1 to AE3, respectively. For example, the first to third reflective electrodes RFE1 to RFE3 may be formed in the first openings OP1 on the first to third anode electrodes AE1 to AE3. The first to third reflective electrodes RFE1 to RFE3 may be in contact with the first to third anode electrodes AE1 to AE3 and electrically connected thereto.

According to an embodiment, the first to third reflective electrodes RFE1 to RFE3 may overlap areas where the first to third light emitting elements LD1 to LD3 are disposed in a subsequent process. Accordingly, the first to third reflective electrodes RFE1 to RFE3 may form a reflective surface for forming a light recycling structure.

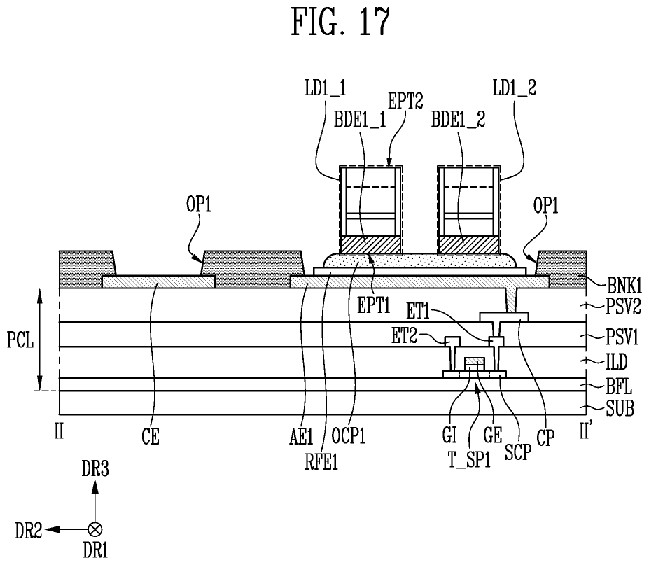

FIG. 16 is a schematic plan view of a display device in S120 and S130 of FIG. 13. FIG. 17 is a schematic cross-sectional view taken along line II-II′ of FIG. 16.

Referring to FIGS. 13, 16 and 17, in S120, the first to third overcoat patterns OCP1 to OCP3 may be formed on first to third anode electrodes AE1 to AE3.

According to an embodiment, the first to third overcoat patterns OCP1 to OCP3 may be formed on the substrate SUB (or pixel circuit layer PCL) based on a process such as deposition, or the like within the spirit and the scope of the disclosure.

The first to third overcoat patterns OCP1 to OCP3 may be formed on the first to third anode electrodes AE1 to AE3 in the first openings OP1. The first to third overcoat patterns OCP1 to OCP3 may be formed to extend in the second direction DR2 and be spaced apart from each other in the first direction DR1. The first to third overcoat patterns OCP1 to OCP3 may partially cover the first to third anode electrodes AE1 to AE3. For example, the first overcoat pattern OCP1 may be disposed to overlap a portion of the first anode electrode AE1. The second overcoat pattern OCP2 may be disposed to overlap a portion of the second anode electrode AE2. The third overcoat pattern OCP3 may be disposed to overlap a portion of the third anode electrode AE3.

In S130, the first to third light emitting elements LD1 to LD3 may be disposed on the first to third overcoat patterns OCP1 to OCP3.

According to an embodiment, the first to third light emitting elements LD1 to LD3 may be disposed on the substrate SUB (or pixel circuit layer PCL) by various transfer methods. The first to third light emitting elements LD1 to LD3 may be respectively disposed on the first to third overcoat patterns OCP1 to OCP3. The first to third light emitting elements LD1 to LD3 may overlap the first to third overcoat patterns OCP1 to OCP3, respectively.

Each of the first to third light emitting elements LD1 to LD3 may include first and second end portions EPT1 and EPT2. Here, the first end portion EPT1 may refer to a portion of a bonding electrode of each of the first to third light emitting elements LD1 to LD3. The second end portion EPT2 may be spaced apart from the first end portion EPT1 in the third direction DR3. The second end portion EPT2 may refer to a portion of an auxiliary layer of each of the first to third light emitting elements LD1 to LD3. For example, the second end portion EPT2 of each of the first light emitting elements LD1_1 to LD1_2 may be disposed to face upward (for example, in the third direction DR3). Accordingly, the first end portion EPT1 of each of the first light emitting elements LD1_1 to LD1_2 may be in contact with the first overcoat pattern OCP1. And the second end portion EPT2 of each of the first light emitting elements LD1_1 to LD1_2 may be exposed.

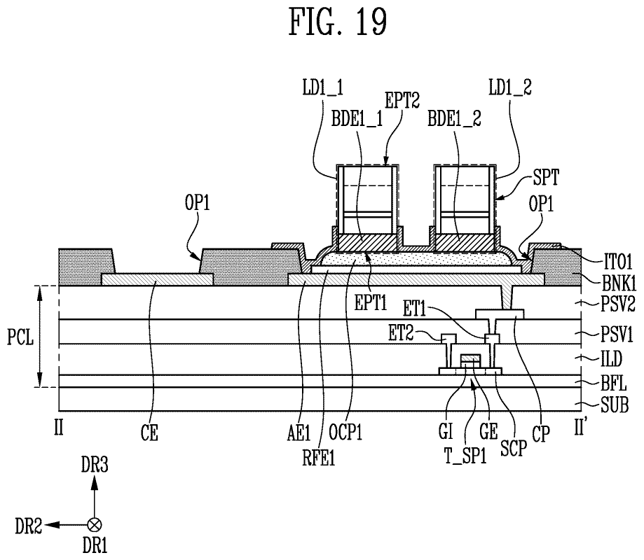

FIG. 18 is a schematic plan view of a display device in S140 of FIG. 13. FIG. 19 is a schematic cross-sectional view taken along line II-II′ of FIG. 18.

Referring to FIGS. 13, 18, and 19, in S140, a first transparent electrode layer ITO1 may be formed on the first to third overcoat patterns OCP1 to OCP3.

According to an embodiment, the first transparent electrode layer ITO1 may be formed overlapping each of the first to third anode electrodes AE1 to AE3. For example, the first transparent electrode layer ITO1 may overlap a portion of the first overcoat pattern OCP1 on the first anode electrode AE1. The first transparent electrode layer ITO1 may overlap a portion of the second overcoat pattern OCP2 on the second anode electrode AE2. The first transparent electrode layer ITO1 may overlap a portion of the third overcoat pattern OCP3 on the third anode electrode AE3.

In the first openings OP1, the first transparent electrode layer ITO1 may be in contact with a portion of the first to third anode electrodes AE1 to AE3. The first transparent electrode layer ITO1 may be in contact with the first to third overcoat patterns OCP1 to OCP3 and the first end portion EPT1 of each of the first to third light emitting elements LD1 to LD3. For example, the first transparent electrode layer ITO1 may be in contact with each side surface EPT1_SS of the bonding electrodes BDE1_1 to BDE3_1. The first transparent electrode layer ITO1 may also be in contact with a portion of a side surface SPT disposed between the first end portion EPT1 and the second end portion EPT2 of each of the first to third light emitting elements LD1 to LD3.

The first transparent electrode layer ITO1 may be electrically connected to the first end portion EPT1 of each of the first to third light emitting elements LD1 to LD3. For example, the first end portion EPT1 of each of the first light emitting elements LD1_1 and LD1_2 may be electrically connected to the first anode electrode AE1 through the first transparent electrode layer ITO1.

Although not shown in FIGS. 18 and 19, another transparent electrode layer overlapping the cathode electrode CE may be additionally formed on the same layer as the first transparent electrode layer ITO1. However, another transparent electrode layer may extend in the first direction DR1 and be disposed across the first to third sub-pixels SP1 to SP3. Another transparent electrode layer may be disposed spaced apart from the first transparent electrode layer ITO1 in the second direction DR2 so as not to overlap the first to third overcoat patterns OCP1 to OCP3.

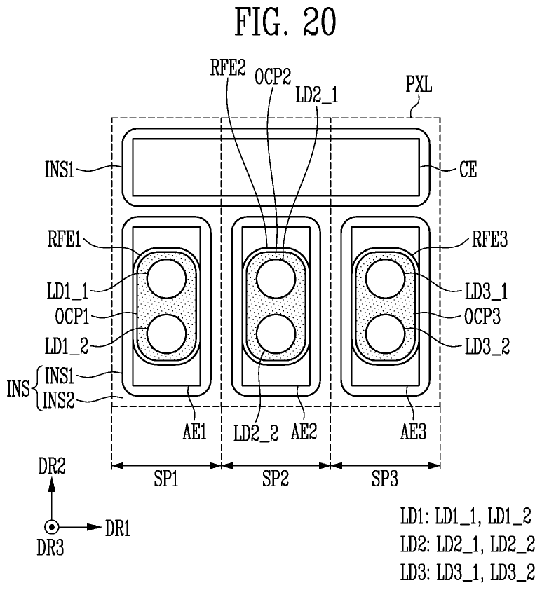

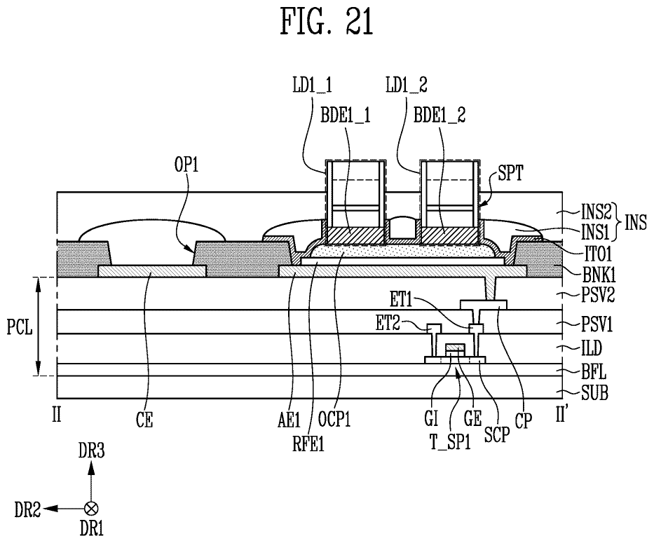

FIG. 20 is a schematic plan view of a display device in S150 of FIG. 13. FIG. 21 is a schematic cross-sectional view taken along line II-II′ of FIG. 20.

Referring to FIGS. 13, 20 and 21, in S150, at least one insulating layer INS may be formed on the first transparent electrode layer ITO1 and the cathode electrode CE.

According to an embodiment, at least one insulating layer INS may include a first insulating layer INS1 disposed on each of the first to third anode electrodes AE1 to AE3 and the cathode electrode CE, and a second insulating layer INS2 disposed on the first insulating layer INS1.

The first insulating layer INS1 may be disposed in the first openings OP1 formed by the first bank BNK1. The first insulating layer INS1 may be provided in an area surrounded by the first bank BNK1. For example, the first insulating layer INS1 may be disposed to overlap each of the first transparent electrode layer ITO1 and the cathode electrode CE. The first insulating layer INS1 may be directly disposed on the first transparent electrode layer ITO1 and may be in contact with the first transparent electrode layer ITO1.

The second insulating layer INS2 may be entirely disposed on the first insulating layer INS1. For example, the second insulating layer INS2 may cover the first insulating layer INS1 and provide a substantially flat upper surface. The second insulating layer INS2 may be directly disposed on the first insulating layer INS1 and may be in contact with the first insulating layer INS1. The second insulating layer INS2 may be in contact with the upper surface of the first bank BNK1 on which the first insulating layer INS1 is not disposed. And the second insulating layer INS2 may be in contact with the side surface SPT of each of the first light emitting elements LD1_1 and LD1_2.

Referring to FIGS. 20 and 21, the first and second insulating layers INS1 and INS2 may be disposed on the first to third anode electrodes AE1 to AE3 and the cathode electrode CE without overlapping the first to third light emitting elements LD1 to LD3.

According to an embodiment, at least one insulating layer INS may be formed on the substrate SUB (or pixel circuit layer PCL) based on a process such as a deposition, or the like within the spirit and the scope of the disclosure. For example, an additional etching process may be performed after at least one insulating layer INS is formed. For example, the first insulating layer INS1 may be formed on the first to third anode electrodes AE1 to AE3 and on the cathode electrode CE through an additional etching process using a halftone mask.

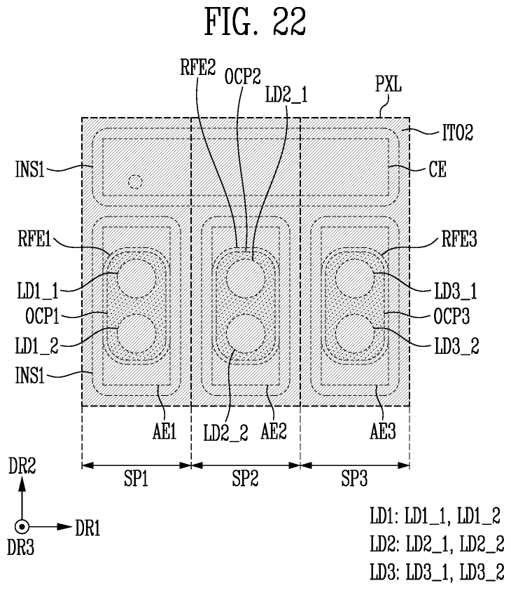

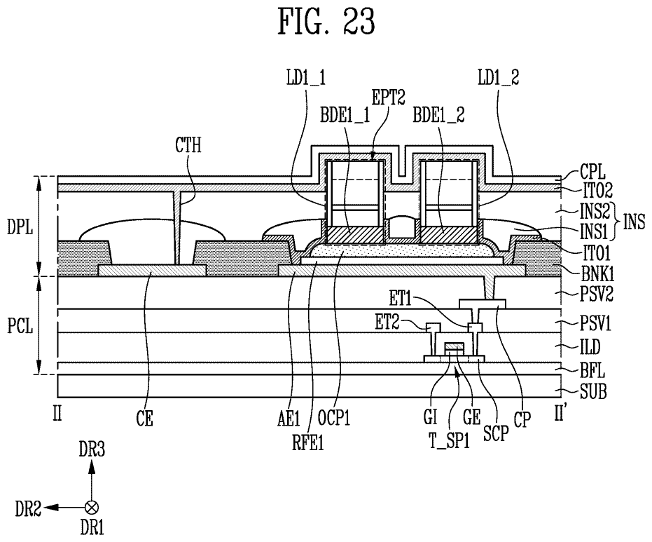

FIG. 22 is a schematic plan view of a display device in S160 of FIG. 13. FIG. 23 is a schematic cross-sectional view taken along line II-II′ of FIG. 22.

Referring to FIG. 13, FIG. 22 and FIG. 23, in S160, a second transparent electrode layer ITO2 may be formed on at least one insulating layer INS. For example, the second transparent electrode layer ITO2 may extend in the second direction DR2 as well as the first direction DR1 on at least one insulating layer INS. The second transparent electrode layer ITO2 may be disposed across the first to third sub-pixels SP1 to SP3 and serve as a common electrode.

According to an embodiment, a contact hole CTH penetrating at least one insulating layer INS may be formed. For example, the contact hole CTH may overlap the cathode electrode CE. And the contact hole CTH may be spaced apart from the first to third light emitting elements LD1 to LD3 in the second direction DR2 without overlapping the first to third light emitting elements LD1 to LD3.

Thereafter, the second transparent electrode layer ITO2 may be connected to the cathode electrode CE through the contact hole CTH. For example, the second transparent electrode layer ITO2 and the cathode electrode CE may be connected by filling the contact hole CTH with a same material as the second transparent electrode layer ITO2.

In S160, the second end portion EPT2 of each of the first light emitting elements LD1_1 and LD1_2 and the second transparent electrode layer ITO2 may be in contact with each other. The second transparent electrode layer ITO2 may be directly disposed on the second end portion EPT2 of each of the first light emitting elements LD1_1 and LD1_2. For example, the cathode electrode CE and the first light emitting elements LD1_1 and LD1_2 may be electrically connected through the second transparent electrode layer ITO2.

Thereafter, a capping layer CPL covering each layer of the display element layer DPL may be formed.

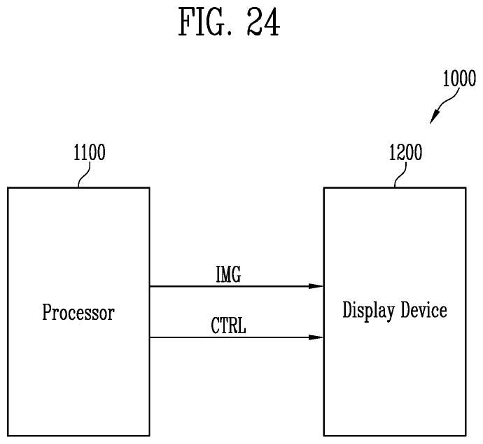

FIG. 24 is a block diagram showing an embodiment of a display system.

Referring to FIG. 24, the display system 1000 may include a processor 1100 and a display device 1200.

The processor 1100 may perform various tasks and calculations. In embodiments, the processor 1100 may include an application processor, a graphic processor, a microprocessor, a central processing unit CPU, and the like within the spirit and the scope of the disclosure. The processor 1100 may be connected to and control other components of the display system 1000 through a bus system.

The processor 1100 may transmit image data IMG and a control signal CTRL to the display device 1200. The display device 1200 may display an image based on the image data IMG and the control signal CTRL. The display device 1200 may be configured similarly to the display device 1200 described with reference to FIG. 1. In this case, the image data IMG and the control signal CTRL may be provided as the input image data IMG and control signal CTRL of FIG. 1, respectively.

The display system 1000 may include a computing system that provides video display functions, such as a smart watch, a mobile phone, a smart phone, a portable computer, a tablet personal computer, a watch phone, an automotive display, a smart glass, a portable multimedia player (PMP), a navigation, and an ultra-mobile personal computer (UMPC). The display system 1000 may include at least one of a head mounted display (HMD) device, a virtual reality (VR) device, a mixed reality (MR) device, an augmented reality (AR) device, and the like within the spirit and the scope of the disclosure.

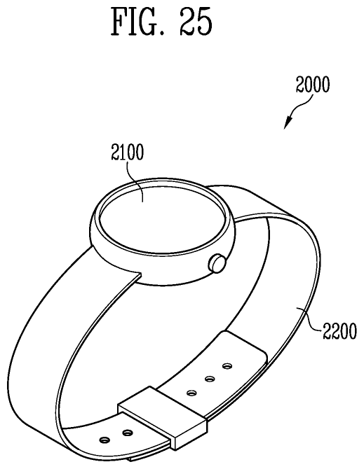

FIGS. 25 to 28 are schematic perspective views showing application examples of a display system of FIG. 24.

Referring to FIG. 25, the display system 1000 of FIG. 24 may be applied to a smart watch 2000 including a display unit 2100 and a strap unit 2200.

The smart watch 2000 may be a wearable electronic device. For example, the smart watch 2000 may have a structure in which the strap unit 2200 is mounted on the user's wrist. Here, the display system 1000 and/or the display device 1200 may be applied to the display unit 2100, and image data including time information may be provided to the user.

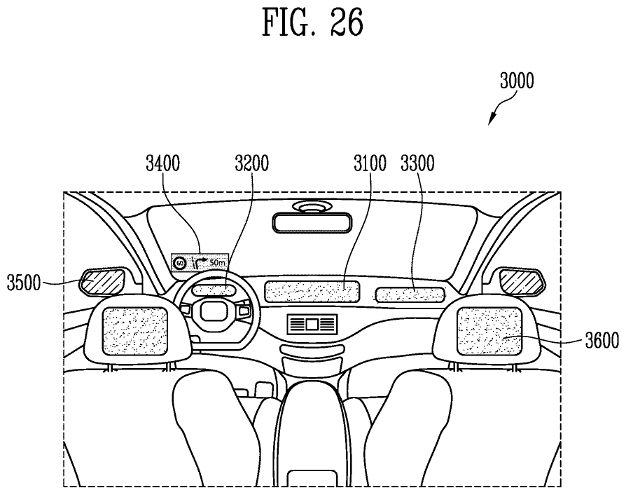

Referring to FIG. 26, the display system 1000 of FIG. 24 may be applied to an automotive display system 3000. Here, the automotive display system 3000 may include a computing system provided inside and/or outside the vehicle to provide image data.

For example, the display system 1000 and/or the display device 1200 may be applied to at least one of an infotainment panel 3100, a cluster 3200, a co-driver display 3300, a head-up display 3400, a side mirror display 3500, and a rear-seat display 3600, provided in the vehicle.

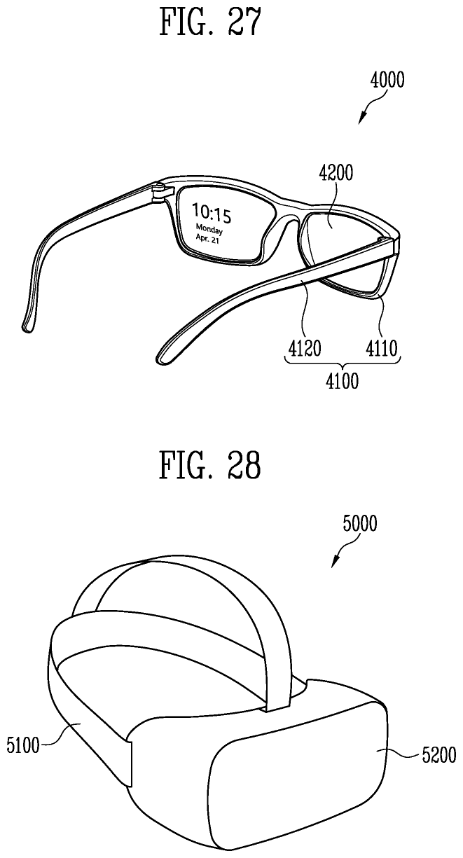

Referring to FIG. 27, the display system 1000 of FIG. 24 may be applied to smart glasses 4000. The smart glasses 4000 may be a wearable electronic device that may be worn on the user's head. For example, the smart glasses 4000 may be a wearable device for augmented reality.

The smart glasses 4000 may include a frame 4100 and a lens unit 4200. The frame 4100 may include a housing 4110 supporting the lens unit 4200 and a leg part 4120 for the user to wear. The leg part 4120 may be connected to the housing 4110 through a hinge and may be folded or unfolded relative to the housing 4110.

A battery, a touch pad, a microphone, a camera, and the like may be embedded in the frame 4100. A projector for outputting light, a processor for controlling light signals, and the like may be embedded in the frame 4100.

The lens unit 4200 may include an optical member that transmits or reflects light. For example, the lens unit 4200 may include glass, transparent synthetic resin, or the like within the spirit and the scope of the disclosure.

In order for the user's eyes to recognize visual information, the lens unit 4200 may reflect an image by the light signal transmitted from the projector of the frame 4100 by using a back surface (for example, surface facing the user's eyes). of the lens unit 4200. For example, the user may recognize visual information such as time and date displayed on the lens unit 4200. At this time, the projector and/or lens unit 4200 may be a type of display device. The display device 1200 may be applied to the projector and/or the lens unit 4200.

Referring to FIG. 28, the display system 1000 of FIG. 24 may be applied to a head mounted display device 5000.

The head mounted display device 5000 may be a wearable electronic device that may be worn on the user's head. For example, the head mounted display device 5000 may be a wearable device for virtual reality or mixed reality.

The head mounted display device 5000 may include a head mounting band 5100 and a display device storage case 5200. The head mounting band 5100 may be connected to the display device storage case 5200. The head mounting band 5100 may include a horizontal band and/or a vertical band for fixing the head mounted display device 5000 to the user's head. The horizontal band may be configured to surround the sides of the user's head, and the vertical band may be configured to surround the top of the user's head. However, the embodiments are not limited thereto. For example, the head mounting band 5100 may be implemented in the form of a glasses frame, a helmet, etc.

The display device storage case 5200 may accommodate the display system 1000 and/or the display device 1200.

In the display device according to embodiments, the first transparent electrode layer ITO1 connected to the first to third anode electrodes AE1 to AE3 may be formed to be in contact with the first end portion EPT1 of the first to third light emitting elements LD1_1 to LD3_1, and the second transparent electrode layer ITO2 connected to the cathode electrode CE may be formed to be in contact with the second end portion EPT2 of the first to third light emitting elements LD1_1 to LD3_1, thereby increasing a contact area and improving stability.

According to embodiments, a display device with improved display quality and a manufacturing method thereof are provided.

Effects according to embodiments are not limited by contents described above, and more various effects are included in the specification.

Although embodiments and applications are described herein, other embodiments and variations may be derived from the description. Accordingly, the spirit of the disclosure is not limited to these embodiments but extends to the scope of the claims set forth below, various obvious modifications, and equivalents.

What is claimed is:

1. A display device comprising:
a substrate extending in a first direction and a second direction intersecting the first direction; and
a display element layer disposed on the substrate in a third direction intersecting the first direction and the second direction, wherein
the display element layer includes:
an anode electrode and a cathode electrode spaced apart from each other in the second direction on the substrate,
an overcoat pattern disposed on the anode electrode,
a light emitting element disposed on the overcoat pattern, the light emitting element including a first end portion adjacent to the overcoat pattern and a second end portion spaced apart from the first end portion in the third direction,
a first transparent electrode layer disposed on the overcoat pattern and electrically connecting the anode electrode to the first end portion of the light emitting element,
at least one insulating layer disposed on the first transparent electrode layer and the cathode electrode, and
a second transparent electrode layer disposed on at least one insulating layer and electrically connecting the cathode electrode to the second end portion of the light emitting element.

2. The display device of claim 1, wherein
the second transparent electrode layer contacts the second end portion of the light emitting element and is electrically connected to the cathode electrode through a contact hole penetrating the at least one insulating layer.

3. The display device of claim 2, wherein
the contact hole overlaps the cathode electrode.

4. The display device of claim 2, wherein
the contact hole is spaced apart from the light emitting element in the second direction without overlapping the light emitting element.

5. The display device of claim 1, wherein
the first transparent electrode layer contacts the overcoat pattern and the first end portion of the light emitting element, and
the second transparent electrode layer electrically contacts the second end portion of the light emitting element.

6. The display device of claim 5, wherein
the overcoat pattern is disposed between the anode electrode and the first end portion of the light emitting element.

7. The display device of claim 6, wherein
the first end portion of the light emitting element contacts the overcoat pattern.

8. The display device of claim 5, wherein
the at least one insulating layer includes:
a first insulating layer disposed on each of the anode electrode and the cathode electrode, and
a second insulating layer disposed on the first insulating layer.

9. The display device of claim 8, wherein
the first insulating layer contacts the first transparent electrode layer.

10. The display device of claim 8, wherein
the light emitting element has a side surface disposed between the first end portion and the second end portion of the light emitting element, and
the second insulating layer contacts the side surface of the light emitting element.

11. The display device of claim 1, wherein
the first transparent electrode layer and the second transparent electrode layer are spaced apart from each other in the third direction with the at least one insulating layer disposed between the first transparent electrode layer and the second transparent electrode layer and include a same material.

12. The display device of claim 1, further comprising:
a bank disposed on the anode electrode and the cathode electrode, and including openings exposing a portion of each of the anode electrode and the cathode electrode, wherein
a portion of the anode electrode and the first transparent electrode layer contact each other in one of the openings of the bank.

13. A display device comprising:
a substrate extending in a first direction and a second direction intersecting the first direction; and
a display element layer disposed on the substrate in a third direction intersecting the first direction and the second direction, wherein
the display element layer includes:
an anode electrode disposed on the substrate,
an overcoat pattern disposed on the anode electrode,
a light emitting element disposed on the overcoat pattern, the light emitting element including a first end portion adjacent to the overcoat pattern and a second end portion spaced apart from the first end portion in the third direction,
a first transparent electrode layer disposed on the overcoat pattern and electrically connecting the anode electrode to the first end portion of the light emitting element,
at least one insulating layer disposed on the first transparent electrode layer, and
a cathode electrode disposed on the at least one insulating layer and electrically connected to the second end portion of the light emitting element, and
the first transparent electrode layer electrically contacts the first end portion of the light emitting element.

14. The display device of claim 13, wherein
the first transparent electrode layer contacts the first end portion of the light emitting element and the overcoat pattern.

15. The display device of claim 13, wherein
the overcoat pattern is disposed between the anode electrode and the first end portion of the light emitting element.

16. The display device of claim 13, wherein
the first end portion of the light emitting element contacts the overcoat pattern.

17. An electronic device comprising a display device and a substrate, wherein
the display device includes the display element layer of claim 1, and
the display element layer is disposed on the substrate.

18. The electronic device of claim 17, wherein the electronic device is at least one of a smart watch, a mobile phone, a smartphone, a portable computer, a tablet personal computer (PC), a watch phone, an automotive display, a smart glass, a portable multimedia player (PMP), a navigation system, an ultra mobile computer (UMPC), a head mounted display (HMD) device, a virtual reality (VR) device, a mixed reality (MR) device, and an augmented reality (AR) device.
